(19) United States
(12) Patent Application Publication
(10) Pub. No.: US 2025/0098502 A1
(43) Pub. Date: Mar. 20, 2025

(54) LIGHT EMITTING DISPLAY DEVICE

(71) Applicant: Samsung Display Co., LTD., Yongin-si (KR)

(72) Inventors: Chan Young KIM, Yongin-si (KR); Sang Woo KANG, Yongin-si (KR); DOOHYUN PARK, Yongin-si (KR); Ha Seok JEON, Yongin-si (KR); Seong-Yong HWANG, Yongin-si (KR); Choong Youl IM, Yongin-si (KR)

(21) Appl. No.: 18/664,096

(22) Filed: May 14, 2024

(30) Foreign Application Priority Data
Sep. 19, 2023 (KR) 10-2023-0124978

(51) Int. Cl. H10K 59/80; H10K 59/122; H10K 102/00

(52) U.S. Cl. CPC H10K 59/8792; H10K 59/122; H10K 2102/311

(57) ABSTRACT

The light emitting display device includes a substrate including a first display area and a bending display area, an anode on the substrate, a pixel defining layer having an opening exposing at least a portion of the anode, a light emitting layer in the opening of the pixel defining layer, a cathode covering the pixel defining layer and the light emitting layer, a encapsulation layer covering the cathode, and a light blocking layer on the encapsulation layer and having an opening corresponding to the opening of the pixel defining layer, wherein the opening of the pixel defining layer includes a first opening and a second opening, and the opening of the light blocking layer includes a first display opening in the first display area and a bending opening in the bending display area, and the bending opening is different in position, shape, or size from the first display opening.

### CROSS-REFERENCE TO RELATED APPLICATION

The present application claims priority to and the benefit of Korean Patent Application No. 10-2023-0124978, filed on Sep. 19, 2023, in the Korean Intellectual Property Office, the entire content of which is hereby incorporated by reference.

### BACKGROUND

### 1. Field

Embodiments of the present disclosure relate to a light emitting display device, and for example, to a light emitting display device including a bending area.

### 2. Description of the Related Art

A display device is a device that displays an image (e.g., on a screen), and includes, for example, a liquid crystal display (LCD) device and/or an organic light emitting diode (OLED) device.

These display devices are utilized in various electronic devices such as mobile phones, navigation devices, digital cameras, electronic books, portable game consoles, and/or various suitable (information) terminals.

A display device, such as an organic light emitting display device, may have a structure that can be bent and/or folded utilizing a flexible substrate.

In addition, in small electronic devices such as mobile phones, optical elements such as cameras and optical sensors may be formed in a bezel area around the display area. However, as the size of the display screen increases, the size of the area around (e.g., surrounding) the display area gradually decreases, and camera technology is being pursued and/or developed that allows optical sensors to be positioned on the back of the display area.

### SUMMARY

Aspects of one or more embodiments of the present disclosure relate to an improved display quality due to lowering reflectance of external light and/or reducing a color spreading (color separation) phenomenon caused by reflected light.

Aspects of one or more embodiments of the present disclosure relate to an improved viewing angle and/or luminance from the front due to adjusting the position of the opening of the light blocking layer located in front of the light emitting layer in the bending area.

According to one or more embodiments of the present disclosure, a light emitting display device includes: a substrate including a first (e.g., normal or main) display area and a bending display area; an anode on the substrate; a pixel defining layer having an opening exposing at least a portion of the anode; a light emitting layer within the opening of the pixel defining layer; a cathode covering the pixel defining layer and the light emitting layer; an encapsulation layer covering the cathode; and a light blocking layer on the encapsulation layer and having an opening corresponding to the opening of the pixel defining layer, wherein the opening of the pixel defining layer includes a first opening in the first display area and a second opening in the bending display area, the opening of the light blocking layer includes a first (e.g., normal or main) display opening in the first display area and overlapping the first opening in a plan view of the first display area, and a bending opening in the bending display area and overlapping the second opening in a plan view of the bending display area, the bending opening of the light blocking layer has the same size as the first display opening of the light blocking layer, and a positional relationship between the first display opening of the light blocking layer in the first display area and the first opening of the pixel defining layer is different from a positional relationship between the bending opening of the light blocking layer in the bending display area and the second (e.g., corresponding second) opening of the pixel defining layer.

In one or more embodiments, a position of the bending opening relative to the second opening may be farther in one direction compared to a position of the first display opening relative to the first opening.

In one or more embodiments, the one direction may be toward the first display area.

In one or more embodiments, the one direction may be normal (e.g., perpendicular) to a reference axis to which the light emitting display device is bent.

In one or more embodiments, in the first display area, the first display opening of the light blocking layer and the first opening of the pixel defining layer may have the same center in the plan view of the first display area.

In one or more embodiments, a center of the bending opening of the light blocking layer in the bending display area maybe offset from a center of the second opening of the pixel defining layer.

In one or more embodiments, the first display area may have a flat display surface, and the bending display area may be outside the first display area and may be bent from the flat display surface.

In one or more embodiments, the substrate may include a plurality of bending display areas including the bending display area, each of the bending display areas including a bending opening and a second opening, each of the bending openings overlapping a corresponding one of the second openings in a plan view of a respective one of the bending display areas, a separation distance may be a maximum gap between the first display opening of the light blocking layer and a respective bending opening of the bending openings of the light blocking layer when the first display opening and the respective bending opening are positionally compared relative to the first opening and a corresponding one of the second openings, and, and the separation distance may increase as a distance from the first display area increases.

In one or more embodiments, the separation distance may be greater than 0 and less than or equal to 6 μm.

In one or more embodiments, the substrate may include a plurality of bending display areas including the bending display area, each of the bending display areas including a bending opening and a second opening, each of the bending openings overlapping a corresponding one of the second openings in a plan view of a respective one of the bending display areas, a separation distance may be a maximum gap between the first display opening of the light blocking layer and a respective bending opening of the bending openings of the light blocking layer when the first display opening and the respective bending opening are positionally compared relative to the first opening and a corresponding one of the second openings, and the separation distance of a bending opening of the bending openings located farther from the first display area may be greater than the separation distance of a bending opening of the bending openings located closer to the first display area.

In one or more embodiments, the plurality of bending display areas may include (e.g., may be divided into) a 1-1 bending display area, a 1-2 bending display area, and a 1-3 bending display area, the 1-1 bending display area may be located closest to the first display area, the 1-2 bending display area is between the 1-1 bending display area and the 1-3 bending display area, and the 1-3 bending display area may be located farthest from the first display area, and the separation distance of the light blocking layer in the 1-1 bending display area may be the smallest, the separation distance of the light blocking layers in the 1-3 bending display areas may be the largest, and the separation distance of the light blocking layers in the 1-2 bending display areas may be the second largest (i.e., between the largest and the smallest).

In one or more embodiments, the separation distances of the plurality of bending display areas may each be greater than 0 and less than or equal to 6 μm.

According to In one or more embodiments of the present disclosure, light emitting display device includes: a substrate including a first (e.g., normal or main) display area and a bending display area; an anode on the substrate; a pixel defining layer having an opening exposing at least a portion of the anode; a light emitting layer within the opening of the pixel defining layer; a cathode covering the pixel defining layer and the light emitting layer; an encapsulation layer covering the cathode; and a light blocking layer on the encapsulation layer and having an opening corresponding to the opening of the pixel defining layer wherein the opening of the pixel defining layer includes a first opening in the first display area and a second opening in the bending display area, the opening of the light blocking layer includes a first display opening in the first display area and overlapping the first opening in a plan view of the first display area, and a bending opening in the bending display area and overlapping the second opening in a plan view of the bending display area, and the bending opening of the light blocking layer has a different shape or size from the first display opening of the light blocking layer.

In one or more embodiments, a planar shape of the bending opening relative to the second opening may extend farther in one direction compared to a planar shape of the first display opening relative to the first opening.

In one or more embodiments, an extension distance may be a distance between the planar shape of the bending opening and the planar shape of the first display opening when the bending opening and the first display opening are positionally compared relative to the second opening and the first opening, respectively, and the extension distance may be greater than 0 and less than or equal to 6 μm.

In one or more embodiments, the substrate may include a plurality of bending display areas including the bending area, each of the bending display areas including a bending opening, and the extension distance may increase as a distance from the first display area increases.

In one or more embodiments, the bending opening may have the same center as the second opening and may have a radius or one side larger than the first display opening of the light blocking layer.

In one or more embodiments, a difference between a radius or one side of the first display opening and a radius or one side of the bending opening may be greater than 0 and less than or equal to 6 μm.

In one or more embodiments, the substrate may include a plurality of bending display areas including the bending area, each of the bending areas including a bending opening, and the bending openings may increase in size as a distance from the first display area increases.

In one or more embodiments, the bending display area may include (e.g., may be divided into) a 1-1 bending display area, a 1-2 bending display area, and a 1-3 bending display area, the 1-1 bending display area is closest to the first display area, the 1-2 bending display area is between the 1-1 bending display area and the 1-3 bending display area, the 1-3 bending display area is farthest from the first display area, each of the 1-1 bending display area, the 1-2 bending display area, and the 1-3 bending display area include a bending opening and a second opening, each of the bending openings overlapping a corresponding second opening of the second openings in a plan view of a corresponding one of the 1-1, 1-2, and 1-3 bending display areas, in one of (selected from among) the 1-1 bending display area, the 1-2 bending display area, and/or the 1-3 bending display area, a planar shape of the bending opening relative to the second opening extends farther in one direction compared to a planar shape of the first display opening relative to the first opening, in another one of (selected from among) the 1-1 bending display area, the 1-2 bending display area, and/or the 1-3 bending display area, the bending opening may have the same center as the corresponding second opening and has a larger radius or one side than the first display opening of the light blocking layer, in the remaining one of (selected from among) the 1-1 bending display area, the 1-2 bending display area, and/or the 1-3 bending display area, the bending opening may have the same size as the first display opening of the light blocking layer, and a position of the bending opening relative to the corresponding second opening is farther in one direction compared to a position of the first display opening relative to the first opening.

According to one or more embodiments, the rate at which external light is reflected can be reduced by placing a light blocking layer on the light emitting layer.

According to one or more embodiments, compared to the first display area, the position, size, and/or shape of the opening of the light blocking layer located in the bending area is changed so that the light emitted from the light emitting layer is not blocked from the front, thereby improving the viewing angle and/or luminance.

### BRIEF DESCRIPTION OF THE DRAWINGS

FIG. 1 is a schematic perspective view illustrating a light emitting display device according to one or more embodiments of the present disclosure.

FIG. 2 is an exploded perspective view of a light emitting display device according to one or more embodiments of the present disclosure.

FIG. 3 is a block diagram of a light emitting display device according to one or more embodiments of the present disclosure.

FIG. 4 is a perspective view schematically showing a display panel according to one or more embodiments of the present disclosure.

FIG. 5 is a schematic cross-sectional view of a first (e.g., a flat or non-bending) display area of a light emitting display device according to one or more embodiments of the present disclosure.

FIG. 6 is a schematic cross-sectional view of a first (e.g., a flat or non-bending) display area and a bending display area of a light emitting display device according to one or more embodiments of the present disclosure.

FIG. 7 is a plan view schematically dividing a first (e.g., a flat or non-bending) display area and a bending display area in a light emitting display device according to one or more embodiments of the present disclosure.

FIG. 8-FIG. 10 are each a plan view showing the positional relationship between openings of each bending display area in a light emitting display device according to one or more embodiments of the present disclosure.

FIGS. 11-13 are each a graph simulating the luminance ratio according to the position of the opening of the bending area.

FIG. 14-FIG. 18 are each a plan view showing the positional relationship of openings of a bending display area according to one or more embodiments of the present disclosure.

FIG. 19 is a table providing the structure of a bending display area according to one or more embodiments of the present disclosure.

FIG. 20 is a table showing simulated luminance according to the position and viewing angle of the opening.

FIG. 21 and FIG. 22 are each a plan view schematically dividing a first (e.g., a flat or non-bending) display area and a bending display area in a light emitting display device according to one or more embodiments of the present disclosure.

FIG. 23 is a cross-sectional view of a light emitting display device according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. In order to clearly explain the present disclosure, parts that are not relevant to the description may not be provided, and identical or similar components are given the same reference numerals throughout the specification. Unless otherwise noted, like reference numerals denote like elements throughout the attached drawings and the written description, and thus, duplicative descriptions thereof may not be provided.

In one or more embodiments, the relative sizes and thicknesses of elements, components, regions, and layers shown in the drawings may be exaggerated for convenience of explanation, so the present disclosure is not necessarily limited to what is shown. In the drawings, the thicknesses may be enlarged and/or exaggerated to clearly express various layers and regions.

It will be understood that when a component, such as a layer, membrane plate, film, region or substrate, is referred to as being “on,” “connected to,” or “above” another component, it can be directly on, connected to, or above the other component, or one or more intervening components may be present. In addition, it will also be understood that when a component is referred to as being “between” two components, it can be the only component between the two components, or one or more intervening components may also be present.

Conversely, if (e.g., when) an element is said to be “right on top of,” “directly on,” or “directly connected to” another element, it means that there is no other element in between.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

In addition, throughout the specification, if (e.g., when) reference is made to “on a plane,” this refers to when the target portion is viewed from above, and if (e.g., when) reference is made to “in a cross-section,” this refers to when a cross-section of the target portion is cut vertically and viewed from the side.

In addition, throughout the specification, when “connected” is used, this does not only mean when two or more components are directly connected, but when two or more components are indirectly connected through other components, or they are physically connected, and this may include not only the case of being connected or electrically connected, but also the case of each part being substantially integrated, although referred to by different names depending on location or function, being connected to each other.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

In one or more embodiments, throughout the specification, if (e.g., when) a portion such as a wire, layer, film, region, plate, or component is said to “extend in the first or second direction,” this not only refers to a straight shape extending in a direction, but rather, it may be a structure that extends overall along the first or second direction, and may also include a structure that is bent at some part, has a zigzag structure, or extends while including a curved structure.

In addition, electronic devices (e.g., mobile phones, TVs, monitors, laptop computers, and/or the like) containing display devices, display panels, and/or the like described in the specification, or display devices, display panels, and/or the like manufactured by the manufacturing method described in the specification are included as embodiments of the present disclosure.

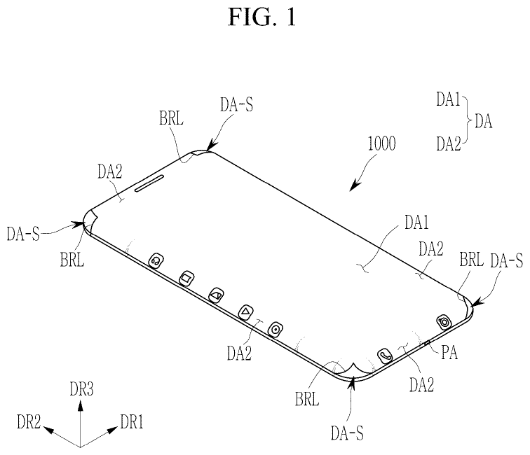

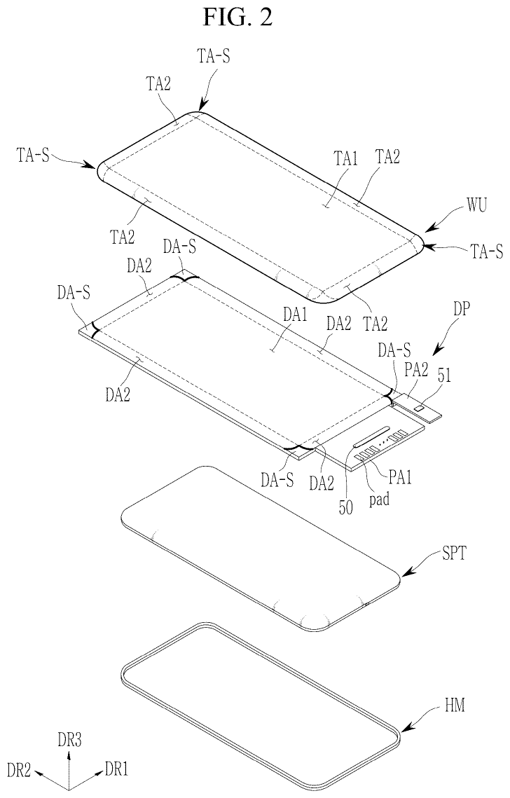

Below, the overall structure of a light emitting display device that includes a first area (e.g., a flat or non-bending area) and a curved bending area of the display area will be described in more detail with reference to FIGS. 1 and 2.

FIG. 1 is a schematic perspective view showing a utilization state of a light emitting display device according to one or more embodiments of the present disclosure, and FIG. 2 is an exploded perspective view of a light emitting display device according to one or more embodiments of the present disclosure.

The light emitting display device 1000 according to one or more embodiments is a device that displays moving images or still images, and is utilized in mobile phones, smart phones, tablet personal computers, mobile communication terminals, and electronic notebooks. Displays of one or more suitable products such as televisions, laptops, monitors, billboards, internet of things (IoT), and/or the like, as well as portable electronic devices such as e-books, portable multimedia players (PMPs), navigation devices, and UMPCs (Ultra Mobile PCs), can utilize the light emitting display device 1000 as a screen.

Also, the light emitting display device 1000 according to one or more embodiments can be utilized in wearable devices such as a smart watch, a watch phone, a glasses-type or kind display, and a head-mounted display (HMD).

In one or more embodiments, the light emitting display device 1000 according to one or more embodiments includes a dashboard of a car, a center information display (CID) placed on the center fascia or dashboard of a car, a room mirror display that replaces the side mirror of a car (room mirror display), and an entertainment unit for the backseat of a car, which can be utilized as a display placed on the back of the front seat.

FIG. 1 shows the light emitting display device 1000 being utilized as a smart phone for convenience of explanation.

In one or more embodiments, the light emitting display device 1000 according to the present embodiment(s) includes a display area DA, where the display area DA includes a first (e.g., normal or main) display area DA1 and a bending display area. It may be divided into areas DA2 and DA-S (e.g., a second display area and auxiliary area), hereinafter also referred to as a bending display area.

The first display area DA1 is parallel to the first direction DR1 and the second direction DR2 and has a flat display surface, and the first bending display area DA2 (DA-S) is located on the outside of the display surface parallel to each direction DA1 and DR2 and at a bent portion of the display surface, and may have a curved structure with a set or predetermined curvature.

The first bending display area DA2, DA-S includes a first bending display area DA2 located to be bent at the side of the first display area DA1, which is the normal (e.g., flat or non-bending) display area. It is divided into a second bending display area DA-S that is bent at a corner of the first display area DA1.

A border BRL may be located between the first bending display area DA2 and the second bending display area DA-S, but in one or more embodiments, the border BRL may not be visible to the user.

Referring to FIG. 2, the light emitting display device 1000 may include a cover window WU, a display panel DP, a support unit SPT, and a housing HM. The cover window WU may be arranged on the front of the display panel DP. In the embodiment of FIG. 2, the front (or upper) and rear (or lower) surfaces of each member are defined based on the third direction DR3. The front and back surfaces are opposed to each other in the third direction DR3, and the normal (perpendicular) directions of each of the front and back surfaces may be parallel to the third direction DR3.

A separation distance between the front and back surfaces in the third direction DR3 may correspond to the thickness of the display panel DP in the third direction DR3.

The cover window WU can protect the display panel DP from external impacts, and/or the like. The cover window WU may include a transparent material. For example, the cover window WU may include glass or a transparent synthetic resin. The cover window WU may include transmitting portions TA1, TA2, and TA-S so that the image can be viewed from the front.

Here, the transmitting portions TA1, TA2, and TA-S include a first transmitting portion TA1 corresponding to the first display area DA1, a first bending transmitting portion TA2 corresponding to the first bending display area DA2, and a second bending transmitting portion TA-S) corresponding to the bending display area DA-S.

The display panel DP includes display areas DA1, DA2, and DA-S, peripheral areas PA1 and PA2 located outside the display areas DA1, DA2, and DA-S, and driving units 50 and 51.

A pixel including a light-emitting element is located in each display area DA1, DA2, DA-S, and may be an area in which the pixel operates according to an electrical signal to emit light.

In one or more embodiments, a touch sensor is located above the display areas DA1, DA2, and DA-S so that external input can be sensed.

Peripheral areas PA1, PA2 may be located in the non-display area outside the display areas DA1, DA2, DA-S.

The first driver 50 is located in the first peripheral area PA1 to drive the pixels located in the display areas DA1, DA2, and DA-S to display images, and in the second peripheral area PA2, the second driving unit 51 is located to detect an external touch. For example, the first driver 50 is electrically connected to the display areas DA1, DA2, and DA-S and can transmit electrical signals to the display areas DA1, DA2, and DA-S. For example, the first driver 50 may provide data signals to pixels arranged in the display areas DA1, DA2, and DA-S.

In one or more embodiments, the light emitting display device 1000 may have a pad portion (pad as shown, for example, in FIG. 2) located at an end of the first peripheral area PA1, and may be electrically connected with a printed circuit board including a drive chip by the pad portion. In one or more embodiments, a pad portion is also formed in the second peripheral area PA2 to receive or transmit information from the outside.

The light emitting display device 1000 according to one or more embodiments can detect a user's input applied from the outside. The user's input may include one or more suitable types (kinds) of external inputs, such as parts of the user's body, light, heat, or pressure. In one or more embodiments, the user's input is performed with the user's hand applied to the front. However, the present disclosure is not limited to this. The user's input may be provided in one or more suitable forms, and the light emitting display device 1000 may detect the user's input applied to the side or back of the light emitting display device 1000 depending on the structure of the light emitting display device 1000.

The support part SPT serves to support the display areas DA1, DA2, DA-S) so that the first display area DA1 has a flat structure and the bending display area DA2, DA-S has a bent structure. The support part SPT may be formed of one or more suitable materials such as glass, plastic, and/or metal. The housing HM may be combined with the cover window WU to configure the exterior of the light emitting display device 1000.

The housing HM can be combined with the cover window WU to provide a set or predetermined accommodation space. The display panel DP and the support part SPT may be accommodated in a set or predetermined accommodation space provided between the housing HM and the cover window WU.

The housing HM may include a material with relatively high rigidity. For example, the housing HM may include a plurality of frames and/or plates made of glass, plastic, or metal, and/or any suitable combination thereof. The housing HM can stably protect the components of the light emitting display device 1000 accommodated in the internal space from external shock.

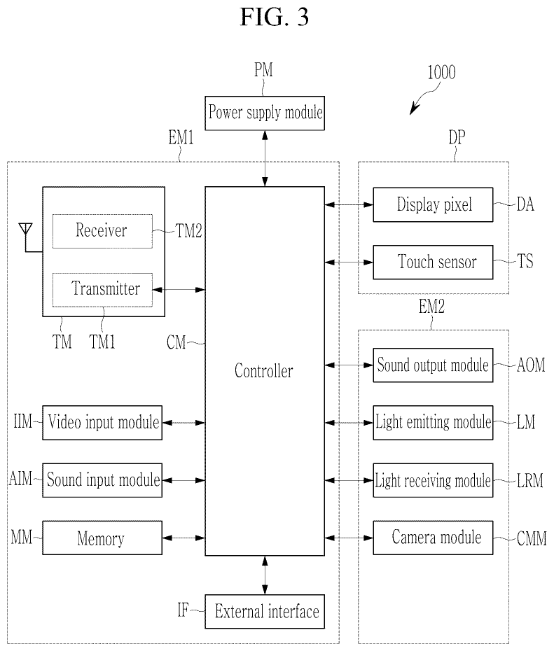

FIG. 3 is a block diagram of a light emitting display device according to one or more embodiments of the present disclosure.

Referring to FIG. 3, the light emitting display device 1000 may include a display panel DP, a power supply module PM, a first electronic module EM1, and a second electronic module EM2.

The display panel DP, the power supply module PM, the first electronic module EM1, and the second electronic module EM2 may be electrically connected to each other.

FIG. 3 illustrates display pixels and a touch sensor TS located in the display area DA among the configuration of the display panel DP.

The power supply module PM can supply power that is desired or required for the overall operation of the light emitting display device 1000.

The power supply module PM may include a battery module utilized in the related art.

The first electronic module EM1 and the second electronic module EM2 may include one or more suitable functional modules for operating the light emitting display device 1000.

The first electronic module EM1 may be mounted directly on a motherboard electrically connected to the display panel DP, or may be mounted on a separate board and electrically connected to the motherboard through a connector.

The first electronic module EM1 may include a control module CM, a wireless communication module TM, an image input module IIM, an audio input module AIM, a memory MM, and an external interface IF. Some of the modules may not be mounted on the motherboard, but may be electrically connected to the motherboard through a flexible printed circuit board connected thereto.

The control module CM can control the overall operation of the light emitting display device 1000. The control module CM may be a microprocessor. For example, the control module CM may activate or deactivate the display panel DP.

The control module CM can control other modules, such as the image input module IIM or the audio input module AIM, based on a touch signal received from the display panel DP.

The wireless communication module TM can transmit/receive wireless signals to and from other terminals utilizing, for example, Bluetooth or Wi-Fi. The wireless communication module TM can transmit/receive voice signals utilizing a general communication line. The wireless communication module TM includes a transmitter TM1 that modulates and transmits a signal to be transmitted, and a receiver TM2 that demodulates the received signal.

The image input module IIM can process video signals and convert them into video data that can be displayed on the display panel DP.

The audio input module AIM can receive external acoustic signals through a microphone in recording mode, voice recognition mode, and/or the like, and convert them into electrical voice data.

The external interface IF may serve as an interface connected to an external charger, wired/wireless data port, card socket (e.g., memory card, SIM/UIM card), and/or the like.

The second electronic module EM2 may include an audio output module AOM, a light emitting module LM, a light receiving module LRM, and a camera module CMM, at least some of which include optical elements ES. It may be located on the back of the display areas DA1, DA2, and DA-S, as shown in FIGS. 1 and 2.

The optical element(s) ES may include a light emitting module LM, a light receiving module LRM, and a camera module CMM.

Also, the second electronic module EM2 can be directly mounted on the motherboard, or mounted on a separate board and electrically connected to the display panel DP through connectors, or it can be electrically connected to the first electronic module EM1.

The audio output module AOM can convert audio data received from the wireless communication module TM or audio data stored in the memory MM and output it to the outside.

The light emitting module LM can generate and output light. The light emitting module LM can output infrared rays. For example, the light emitting module LM may include an LED device.

For example, a light receiving module LRM can detect infrared light. The light receiving module LRM may be activated if (e.g., when) infrared rays above a certain level are detected. The light receiving module LRM may include a CMOS sensor.

After the infrared light generated in the light emitting module LM is output, it is reflected by an external object (e.g., a user's finger or face), and the reflected infrared light may be incident on the light receiving module LRM.

The camera module CMM can capture external images.

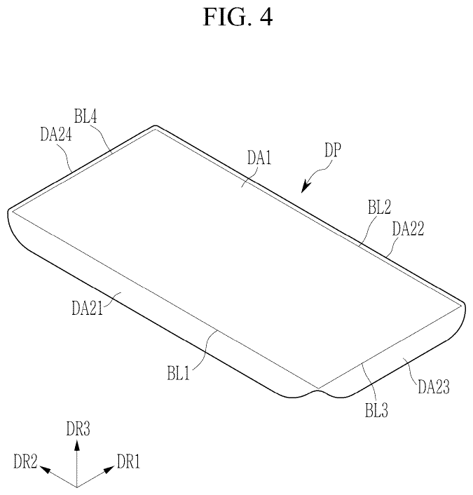

In one or more embodiments, FIG. 4 shows a display panel DP that may be included in the light emitting display device 1000 according to one or more embodiments of the present disclosure.

FIG. 4 is a perspective view schematically showing a display panel according to one or more embodiments of the present disclosure.

The display panel DP shown in FIG. 4 has a structure in which each of the four sides is bent and folded, and the display area DA is folded at the first to fourth bending lines BL1, BL2, BL3, and BL4 to form (or provide) the first display area DA1, so it has a structure divided into the first bending display area DA2, which includes a first side bending display area DA21, a second side bending display area DA22, a third side bending display area DA23, and a fourth side bending display area DA24.

The first display area DA1 may have a rectangular planar shape with the first direction DR1 and the second direction DR2, but the present disclosure is not limited thereto. The first display area DA1 may have a different polygonal, circular, or oval planar shape.

A corner where the first direction DR1 and the second direction DR2 meet in the first display area DA1 may be rounded to have a set or predetermined curvature or may be formed at a right angle.

The first display area DA1 may be formed flat or may include a curved surface.

The bending display areas DA21, DA22, DA23, and DA24 are described in more detail below.

The first side bending display area DA21 may extend from the first side of the first display area DA1. The first side bending display area DA21 is bent along the first bending line BL1 on the first side of the first display area DA1 and may have a first curvature. The bending angle of the first side bending display area DA21 compared to the first display area DA1 may be about or approximately 90 degrees or less. The first side of the first display area DA1 may be the left side of the first display area DA1 as shown, for example, in FIG. 4.

The second side bending display area DA22 may extend from the second side of the first display area DA1. The second side bending display area DA22 is bent along the second bending line BL2 on the second side of the first display area DA1 and may have a second curvature. The second curvature may be substantially the same as or different from the first curvature. The bending angle of the second side bending display area DA22 compared to the first display area DA1 may be about or approximately 90 degrees or less. The second side of the first display area DA1 may be on the right side of the first display area DA1 as shown, for example, in FIG. 4.

The third side bending display area DA23 may extend from the third side of the first display area DA1. The third side bending display area DA23 is bent along the third bending line BL3 on the third side of the first display area DA1 and may have a third curvature. The bending angle of the third side bending display area DA23 compared to the first display area DA1 may be approximately 90 degrees or less. The third side of the first display area DA1 may be below the first display area DA1 as shown, for example, in FIG. 4.

The fourth side bending display area DA24 may extend from the fourth side of the first display area DA1. The fourth side bending display area DA24 is bent along the fourth bending line BL4 on the fourth side of the first display area DA1 and may have a fourth curvature. The fourth curvature may be substantially the same as or different from the third curvature. The bending angle of the fourth side bending display area DA24 compared to the first display area DA1 may be approximately 90 degrees or less. The fourth side of the first display area DA1 may be above the first display area DA1 as shown, for example, in FIG. 4.

In one or more embodiments, the display panel DP may further include the second bending display area DA-S that is bent at a corner as shown in FIG. 2.

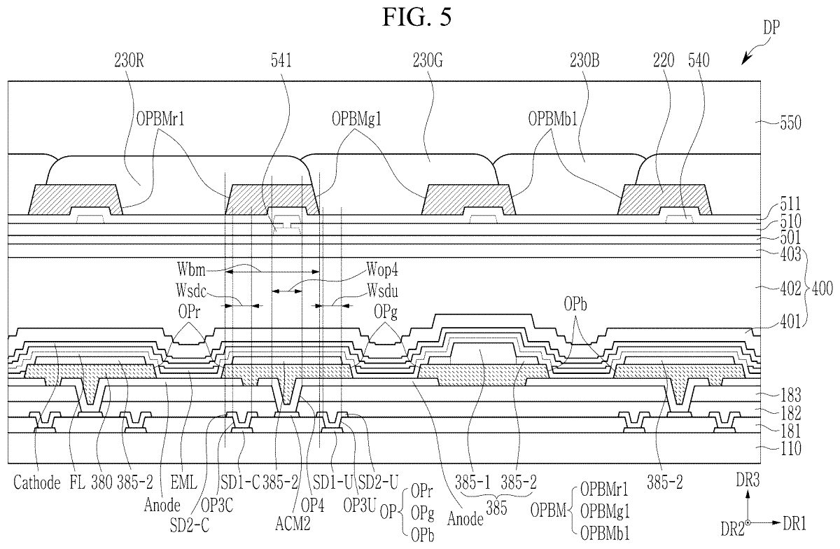

Below, the schematic structure of the first display area DA1 will be described in more detail with reference to FIG. 5.

FIG. 5 is a schematic cross-sectional view of a first display area of a light emitting display device according to one or more embodiments of the present disclosure.

FIG. 5 shows a portion of the display panel DP of a light emitting display device according to one or more embodiments, and is shown utilizing a display panel for a mobile phone.

The display panel DP has a first (e.g., normal or main) display area DA1 located on the front, and the first display area DA1 is formed by a plurality of light-emitting diodes and a plurality of pixel circuit parts that generate and transmit light-emitting current to each of the plurality of light emitting diodes.

Here, one light emitting diode and one pixel circuit part are called a pixel.

In the first display area DA1, one pixel circuit unit and one light emitting diode are formed in a one-to-one arrangement.

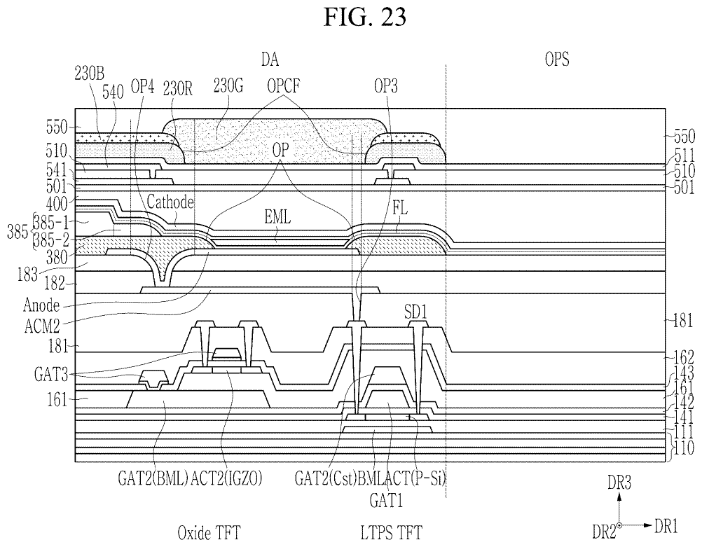

In FIG. 5, the structure between the substrate 110 and the first organic layer 181 according to one or more embodiments will be examined in more detail in FIG. 23.

The first display area DA1 of the display panel DP, according to one or more embodiments, can display an image by a light emitting diode on the substrate 110, and includes a plurality of sensing electrodes 540 and 541 to detect touch. The light emitted from the light emitting diode, including the light blocking layer 220 and color filters 230R, 230G, and 230B, may also have the color characteristics of the color filters 230R, 230G, and 230B.

In one or more embodiments, a polarizer may not be formed on the front of the display panel DP according to one or more embodiments, and instead, the pixel defining layer 380 is utilized, and a light blocking layer 220 and a color filter 230 are formed on the top to block or reduce external light, and even if it enters the inside, it is reflected from the anode, and/or the like, so that it is not transmitted to the user. Also, in the display panel DP according to one or more embodiments, the anode is formed flatly so that the light provided from the outside does not spread asymmetrically from the anode, which can reduce the phenomenon of color spread (color separation) caused by reflected light and improve the display quality.

The display panel DP has a pixel defining layer 380 that separates the light emitting layer EML of the light emitting diodes and is made of a black organic material containing a light blocking material.

The pixel defining layer 380 covering the periphery of the anode contains a light blocking material to block or reduce light, so the anode exposed through the opening OP of the pixel defining layer 380 light is reflected from the anode portion, and the anode is formed entirely flat, or the anode exposed through the opening OP of the pixel defining layer 380 is formed entirely flat, so that the anode is asymmetric to prevent or reduce light from being reflected.

Here, among the openings of the pixel defining layer 380, the opening located in the first display area DA1 may be referred to as a first opening, and the opening located in the bending display area may be referred to as a second opening.

In one or more embodiments, the anode has a structure with the largest step at the opening OP4 (hereinafter also referred to as the anode connection opening OP4) for electrical connection with one end of the pixel circuit unit located below in the third direction DR3, however, the light reflected from this part is the mostly asymmetric.

Accordingly, in one or more embodiments, as shown for example in FIG. 5, the anode connection opening OP4 has a structure that overlaps the pixel defining layer 380 and the light blocking layer 220 and is obscured in a plan view.

As a result, in FIG. 5, the width Wbm of the light blocking layer 220, which has a narrower width than the pixel defining layer 380, is larger than the width Wop4 of the anode connection opening OP4, and the anode connection opening OP4 has a structure in which the light blocking layer 220 overlaps the entire width Wop4 on a plane (e.g., in a plan view).

In one or more embodiments, the pixel defining layer 380 also has a structure that overlaps and covers the entire anode connection opening OP4 on a plane (e.g., in a plan view).

In one or more embodiments, the anode connection opening OP4 is shown to have a structure that at least partially overlaps the sensing electrodes 540 and 541.

In FIG. 5, the widths of the sensing electrodes 540 and 541 and the anode connection opening OP4 are shown to be identical to each other. However, in one or more embodiments, the anode connection opening OP4 is connected to the sensing electrodes 540 and 541, and it can have a structure where all of it overlaps on a plane or only a part of it overlaps on a plane, and it can also have different widths.

The center of the anode connection opening OP4 may have a structure that overlaps the sensing electrodes 540 and 541.

In the display panel DP of FIG. 5, a spacer 385 having a stepped structure is formed on the pixel defining layer 380.

The spacer 385 has a relatively high first part 385-1, and a second part 385-2 that is lower in height than the first part 385-1 and is located around the first part 385-2.

The spacer 385 can reduce the incidence of defects due to pressing pressure by increasing the scratch strength on the display panel DP, and also increases the adhesion with the functional layer FL located on the top of the spacer 385 to prevent or reduce moisture infiltration from the outside, and prevent or reduce air from being injected.

In one or more embodiments, relatively high adhesive strength has the advantage of eliminating or reducing the problem of poor adhesion between layers if (e.g., when) the display panel DP has flexible characteristics and is folded and unfolded.

The display panel DP according to one or more embodiments, as shown, for example, in FIG. 5, is described in more detail below.

The substrate 110 may include a material that has rigid properties and does not bend, such as glass, or may include a flexible material that can bend, such as plastic or polyimide.

A pixel is formed on the substrate 110, and one pixel includes a light-emitting diode and a pixel circuit unit in which a plurality of transistors and capacitors that transmit light emitting current to the light emitting diode are formed.

FIG. 5 shows only a portion of the pixel circuit unit, and the structure of the pixel circuit unit may vary depending on the embodiment(s), and an example of one or more embodiments is shown in FIG. 23.

In FIG. 5, the first data conductive layer SD1 constituting the pixel circuit unit is shown.

For example, a plurality of thin film transistors are formed on the substrate 110, and the first data conductive layer SD1 (including SD1-C and SD1-U) and the second data conductive layer SD2 (including SD2-C and SD2-U) are shown among the plurality of layers constituting the thin film transistor, and in addition, organic layers (the first organic layer 181, the second organic layer 182, and the third organic layer 183) located here are shown.

An anode (see. e.g., “Anode” on FIG. 5) constituting a part of a light emitting diode is located above the third organic layer 183 based on the third direction DR3, and a pixel circuit connected to the light emitting diode is located below the third organic layer 183.

A plurality of layers and insulating layers may also be positioned between the substrate 110 and the first data conductive layer SD1.

In FIG. 5, three organic layers are included to improve the flatness characteristics of the anode, and two organic layers (the second organic layer 182 and the third organic layer 183) are formed on the second data conductive layer SD2.

Also, the anode is electrically connected to the anode connection electrode ACM2 formed in the second data conductive layer SD2 through the anode connection opening OP4 formed in the second organic layer 182 and the third organic layer 183.

The anode includes the anode connection opening OP4 formed on the second organic layer 182 and the third organic layer 183 to be electrically connected to one end of the pixel circuit portion located below in the third direction DR3 and is electrically connected to the anode connection electrode ACM2.

In one or more embodiments, as shown, for example, in FIG. 5, the second data conductive layers SD2-U, SD2-C and the first data conductive layer SD1-U, SD1-C that are connected to each other through an opening (hereinafter also referred to as a lower organic layer opening OP3U, OP3C) formed in the first organic layer 181 are also shown.

The lower organic layer openings OP3U, OP3C, the second data conductive layer SD2-U, SD2-C, and the first data conductive layer SD1-U, SD1-C can be broadly divided into two types (kinds). The classification and explanation are described in more detail below.

The first lower organic layer opening OP3U is an opening that connects the 1-1 data conductive layer SD1-U and the 2-1 data conductive layer SD2-U.

The first lower organic layer opening OP3U is formed in a position that overlaps the pixel defining layer 380 in a plan view, but does not overlap the light blocking layer 220.

As a result, the first lower organic layer opening OP3U is not obscured in a plan view by the light blocking layer 220, but has a structure that is obscured by the pixel defining layer 380.

In one or more embodiments, the first lower organic layer opening OP3U may be partially covered in a plan view by the light blocking layer 220.

The first lower organic layer opening OP3U may overlap the opening OPBM of the light blocking layer 220 in a plan view, and because the color filter is located in the opening OPBM of the light blocking layer 220, it overlaps the color filter in a plan view.

In one or more embodiments, the color filter that overlaps the first lower organic layer opening OP3U on a plane (e.g., in a plan view) may be a green color filter.

In one or more embodiments, the second lower organic layer opening OP3C is an opening that connects the 1-2 data conductive layer SD1-C and the 2-2 data conductive layer SD2-C.

The second lower organic layer opening OP3C is formed at a location that overlaps the pixel defining layer 380 and the light blocking layer 220 in a plan view.

As a result, the second lower organic layer opening OP3C has a structure that is obscured by the light blocking layer 220 and the pixel defining layer 380.

For example, in one or more embodiments, the lower organic layer opening OP3 may be formed at a location that overlaps the pixel defining layer 380 on the plane (e.g., in a plan view), and may or may not overlap the light blocking layer 220 on the plane (e.g., in a plan view).

The lower organic layer opening OP3 may or may not overlap the sensing electrodes 540 and 541 on a plane (e.g., in a plan view).

A light emitting diode including an anode, a light emitting layer EML, and a cathode is located on the third organic layer 183.

An anode may be composed of a single layer containing a transparent conductive oxide film and a metal material, or multiple layers containing these.

The transparent conductive oxide film may include ITO (Indium Tin Oxide), poly-ITO, IZO (Indium Zinc Oxide), IGZO (Indium Gallium Zinc Oxide), and/or ITZO (Indium Tin Zinc Oxide), and the metal material may include silver (Ag), molybdenum (Mo), copper (Cu), gold (Au), and/or aluminum (Al).

The light emitting layer EML may be formed of an organic light emitting material, and adjacent light emitting layers EML may display different colors.

In one or more embodiments, each light emitting layer EML may provide light of the same color due to the color filters 230R, 230G, and 230B located at the top to modify the color light that is displayed to the outside.

A pixel defining layer 380 is located on the third organic layer 183 and the anode. The pixel defining layer 380 has an opening OP, the opening overlaps a part of the anode, and the light emitting layer EML is located on the anode exposed by the opening OP.

The light emitting layer EML may be located only within the opening OP of the pixel defining layer 380 and is separated from the adjacent light emitting layers EML by the pixel defining layer 380.

The pixel defining layer 380 may be formed of a negative type or kind of black organic material.

The black organic material may include a light blocking material, and the light blocking material may include carbon black, carbon nanotubes, a resin or paste containing a black dye, metal particles such as nickel, aluminum, molybdenum, and/or alloys thereof, metal oxide particles, chromium nitride, and/or the like.

The pixel defining layer 380 contains a light blocking material and is black in color, and may have characteristics of absorbing/blocking light rather than reflecting it.

Because the negative type or kind uses organic materials, it can have the property of removing the part covered by the mask.

Here, the pixel defining layer 380 may be formed as a negative type or kind, and the spacer 385 may be formed as a positive type or kind, and may include the same materials.

The spacer 385 is formed on the pixel defining layer 380. The spacer 385 includes a first part 385-1 that is tall and located in a relatively narrower area, and a second part 385-2 that is relatively low in height and is located in a wider area around the narrower area.

In FIG. 5, the first part 385-1 and the second part 385-2 are shown separately through a line within the spacer 385, but in reality, they may be formed as one spacer. Here, the first part 385-1 may serve to secure rigidity against pressing pressure while enhancing scratch strength. The second portion 385-2 may serve to assist contact between the pixel defining layer 380 and the upper functional layer FL. The first part 385-1 and the second part 385-2 are made of the same material, and may be made of a positive type or kind of photosensitive organic material, for example, photosensitive polyimide (PSPI).

Because it has positive characteristics, parts not covered by the mask can be removed.

The spacer 385 is transparent so that light can be transmitted and/or reflected.

Most of the upper surface of the pixel defining layer 380 is covered by the spacer 385, and the edge of the second portion 385-2 has a structure that is spaced and/or apart (e.g., spaced apart) from the edge of the pixel defining layer 380, and a portion of the pixel defining layer 380 may have a structure that is not covered by the spacer 385.

The second part 385-2 covers the upper surface of the pixel defining layer 380 where the first part 385-1 is not located, thereby strengthening the adhesion characteristics between the pixel defining layer 380 and the functional layer FL.

Here, the spacer 385 is made of photosensitive polyimide (PSPI) and may be made of a positive type or kind of organic material.

Depending on the location, only the second part 385-2 of the spacer 385 may be provided.

The functional layer FL is located on the emitting layer EML, the spacer 385, and the exposed pixel defining layer 380, and the functional layer FL may be formed on the front surface of the display panel DP.

The functional layer FL may include an electron injection layer, an electron transport layer, a hole transport layer, and a hole injection layer, and the functional layer FL may be located above and below the light emitting layer EML.

For example, the hole injection layer, hole transport layer, light emitting layer EML, electron transport layer, electron injection layer, and cathode (see, e.g., “Cathode” on FIG. 5) are sequentially located on the anode (Anode), the hole injection layer and hole transport layer among the functional layers FL can be located below the light emitting layer EML, and the electron transport layer and electron injection layer can be located above the light emitting layer EML.

The cathode may be formed as a light-transmitting electrode or a reflective electrode.

In one or more embodiments, the cathode may be a transparent or translucent electrode, and may be lithium (Li), calcium (Ca), lithium/calcium fluoride (LiF/Ca), lithium/aluminum fluoride (LiF/AI), aluminum (Al), silver (Ag), and/or magnesium (Mg), and their compounds can be formed as a metal thin film with a small work function.

Additionally, a transparent conductive oxide (TCO) film, such as indium tin oxide (ITO), indium zinc oxide (IZO), zinc oxide (ZnO), or indium oxide (In₂O₃), may be further arranged on the metal thin film.

The cathode may be formed integrally over the entire surface of the display panel DP.

An encapsulation layer 400 is located on the cathode. The encapsulation layer 400 includes at least one inorganic layer and at least one organic layer, and in FIG. 5, it has a triple-layer structure including a first inorganic encapsulation layer 401, an organic encapsulation layer 402, and a second inorganic encapsulation layer 403.

The encapsulation layer 400 may be utilized to protect the light emitting layer EML made of an organic material from moisture or oxygen that may enter from the outside. In one or more embodiments, the encapsulation layer 400 may include a structure in which an inorganic layer and an organic layer are further sequentially stacked.

Sensing insulating layers 501, 510, and 511 and a plurality of sensing electrodes 540 and 541 are positioned on the encapsulation layer 400 for touch detection.

In one or more embodiments, touch is detected by a capacitive type or kind, utilizing two sensing electrodes 540 and 541, but in one or more embodiments, touch can also be detected by a self-capacitive type or kind, utilizing only one sensing electrode.

The plurality of sensing electrodes 540 and 541 may be insulated with the sensing insulating layers 501, 510, and 511 interposed therebetween, and some may be electrically connected through openings located in the sensing insulating layers 501, 510, and 511.

Here, the sensing electrodes 540 and 541 are made of metal or metal alloy such as aluminum (AI), copper (Cu), silver (Ag), gold (Au), molybdenum (Mo), titanium (Ti), and/or tantalum (Ta), and they may include a single layer or multiple layers.

In one or more embodiments, as shown in FIG. 5, a lower sensing insulating layer 501 is located below the lower sensing electrode 541, and intermediate sensing insulating layer 510 is located between the lower sensing electrode 541 and the upper sensing electrode 540, and in this position, an upper sensing insulating layer 511 is located between the upper sensing electrode 540 and the light blocking layer 220.

The upper sensing insulating layer 511 may be located below the color filters 230R, 230G, and 230B.

At least a portion of the sensing electrodes 540 and 541 may have a structure that overlaps the anode connection opening OP4 on a plane (e.g., in a plan view).

A light blocking layer 220 and color filters 230R, 230G, and 230B are located on the upper sensing electrode 540.

The light blocking layer 220 may be positioned to overlap the sensing electrodes 540 and 541 on a plane (e.g., in a plan view).

The light blocking layer 220 has an opening OPBM, and the opening OPBM of the light blocking layer 220 overlaps the opening OP of the pixel defining layer 380 on a plane (e.g., in a plan view).

Additionally, the opening OPBM of the light blocking layer 220 may be formed wider than the opening OP of the pixel defining layer 380.

As a result, the anode that overlaps the opening OP of the pixel defining layer 380 (i.e., is exposed by the opening OP of the pixel defining layer 380) is also exposed on a plane (e.g., in a plan view) by the light blocking layer 220, so it can have a structure that is not obscured.

This is to ensure that the anode and the light emitting layer EML capable of displaying an image are not obscured by the light blocking layer 220 and the sensing electrodes 540 and 541.

In one or more embodiments, the light blocking layer 220 has a structure that overlaps the anode connection opening OP4 and the second lower organic layer opening OP3C in a plan view, but does not overlap the first lower organic layer opening OP3U in a plan view.

Color filters 230R, 230G, and 230B are located above the sensing insulating layers 501, 510, and 511 and the light blocking layer 220, and within the opening OPBM of the light blocking layer 220.

The color filters 230R, 230G, 230B may include a red color filter 230R that transmits red light, a green color filter 230G that transmits green light, and a blue color filter 230B that transmits blue light.

Each of the color filters 230R, 230G, and 230B may be positioned to overlap the anode of the light emitting diode on a plane (e.g. in a plan view).

In one or more embodiments, because the light emitted from the emitting layer EM may change to a corresponding color as it passes through a color filter, all light emitted from the emitting layer (EML may have the same color. However, the light emitting layer EML may be to emit light of different colors, and the displayed color can be strengthened by passing through a color filter of the same color. In one or more embodiments, the color filters 230R, 230G, and 230B may be replaced with a color conversion layer or may further include a color conversion layer. The color conversion layer may include quantum dots.

A planarization layer 550 covering the color filters 230R, 230G, and 230B is positioned on the color filters 230R, 230G, and 230B. The planarization layer 550 is utilized to planarize the upper surface of the light emitting display device, and may be a transparent organic insulating layer containing one or more materials of (e.g., selected from among) the group including (e.g., consisting of) polyimide, polyamide, acrylic resin, benzocyclobutene, and/or phenol resin.

In one or more embodiments, a relatively low refractive layer (e.g., a refractive layer with a relatively low refractive index) and an additional planarization layer may be further positioned on the planarization layer 550 to improve front visibility and light output efficiency of the display device.

Light can be refracted and emitted toward the front by an additional flattening layer with a relatively low refractive characteristic and a relatively high refractive characteristic.

In one or more embodiments, the planarization layer 550 may not be provided and a relatively low refractive layer and an additional planarization layer may be located directly on the color filter 230.

In one or more embodiments, a polarizing plate is not included on top of the planarization layer 550. A polarizer can play a role in preventing or substantially preventing display quality from deteriorating if (e.g., when) external light is incident and reflected by an anode, and/or the like, and is visible to the user.

However, in the embodiment of FIG. 5, the side of the anode is covered with the pixel defining layer 380 to reduce the degree of reflection from the anode, and a light blocking layer 220 is also formed to reduce the degree of incident light, thereby reducing the amount of light incident on the anode, so the light emitting display device of FIG. 5 already contains a structure that prevents or reduces deterioration of display quality.

Therefore, in one or more embodiments, it may not be desired or necessary to separately form (or provide) the polarizer on the front of the display panel DP.

Additionally, in the embodiment of FIG. 5, the anode, which is exposed through the opening OP of the pixel defining layer 380 where external light can be reflected, is formed flatly so that light does not reflect asymmetrically from the anode.

In one or more embodiments, the anode connection opening OP4, which is the most uneven portion of the anode, is covered by the pixel defining layer 380 and the light blocking layer 220 to prevent or reduce the likelihood of light from being reflected asymmetrically.

The display panel DP according to one or more embodiments can be largely divided into a lower panel layer and an upper panel layer.

The lower panel layer is the part where the light emitting diodes that make up the pixel and the pixel circuit unit are located, and may include an encapsulation layer 400 that covers it.

For example, the lower panel layer is formed from the substrate 110 to the encapsulation layer 400 and includes an anode, a pixel defining layer 380, a light emitting layer EML, a spacer 385, a functional layer FL, and a cathode, and it also includes an insulating film, a semiconductor layer, and a conductive layer between the substrate 110 and the anode.

The upper panel layer is the part located above the encapsulation layer 400 and includes a sensing insulating layers 501, 510, 511 capable of detecting touch and a plurality of sensing electrodes 540, 541, and is utilized to block or reduce light, it may include a light blocking layer 220, color filters 230R, 230G, and 230B, and a planarization layer 550.

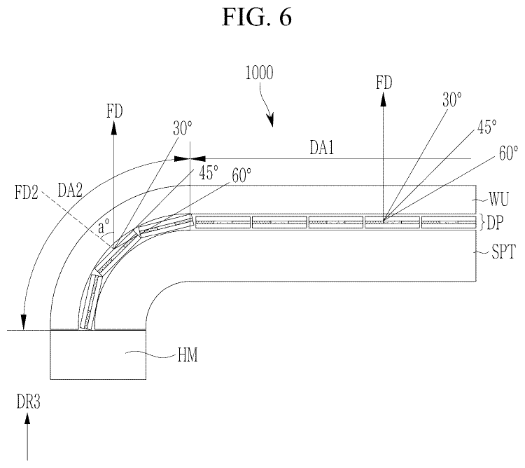

Hereinafter, the structural difference between the first display area DA1 and the first bending display area DA2 will be described in more detail with reference to FIG. 6.

FIG. 6 is a schematic cross-sectional view of a first display area and a bending display area of a light emitting display device according to one or more embodiments.

Referring to FIG. 6, there may be no structural difference between the first display area DA1 and the first bending display area DA2, though the direction of the light emitting layer included in each of the first display area DA1 and the first bending display area DA2 may be different. For example, both the first display area DA1 and the first bending display area DA2 have a support part SPT on the back side, and a cover window WU located on the front side. A housing HM may be located at one end and a rear surface of the support portion SPT.

However, the anode of the display panel DP included in the first display area DA1 has a first normal (e.g., perpendicular) direction FD, and the first normal direction FD is the same direction as the third direction DR3.

Here, the first normal direction FD corresponds to the front of the light emitting display device 1000.

In contrast, the anode of the display panel DP included in the first bending display area DA2 has a different direction from the first normal direction FD, and the light emitting layers of the first bending display area DA2 have a second normal direction FD2, so there may be an angle difference from the first normal direction FD corresponding to the front.

Because the user of the light emitting display device 1000 views the image from the front, that is, the first normal direction FD, the image displayed in the first bending display area DA2 is also viewed based on the first normal direction FD, and the viewing angle of the light emitting display device 1000 is also measured based on the first normal direction FD.

In FIG. 6, examples of viewing angles include 30 degrees, 45 degrees, and 60 degrees.

In one or more embodiments, the opening of the light blocking layer 220 located in front of the light emitting layer is modified so that the image displayed in the first bending display area DA2 can be clearly seen at viewing angles such as 30 degrees, 45 degrees, and 60 degrees.

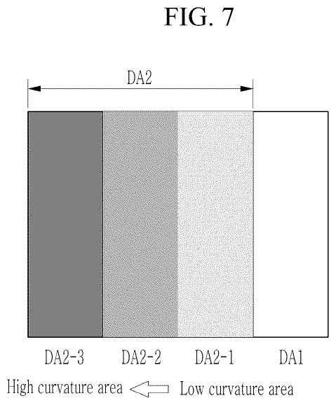

First, one or more embodiments in which the first bending display area DA2 is divided into a plurality of areas as seen in FIG. 7 will be described in more detail.

FIG. 7 is a plan view schematically dividing a first display area and a bending display area in a light emitting display device according to one or more embodiments of the present disclosure.

Referring to FIG. 7, the first bending display area DA2 includes a total of three areas: a 1-1 bending display area DA2-1, a 1-2 bending display area DA2-2, and a 1-3 bending display area DA2-3. Moving outward from the first display area DA1, the 1-1 bending display area DA2-1, the 1-2 bending display area DA2-2, and the 1-3 bending display areas DA2-3 are located sequentially.

As the view moves from the 1-1 bending display area DA2-1 to the 1-3 bending display area DA2-3, the degree of deformation of the opening of the light blocking layer 220 may increase. In one or more embodiments, the curvature may increase from the 1-1 bending display area DA2-1 to the 1-3 bending display area DA2-3.

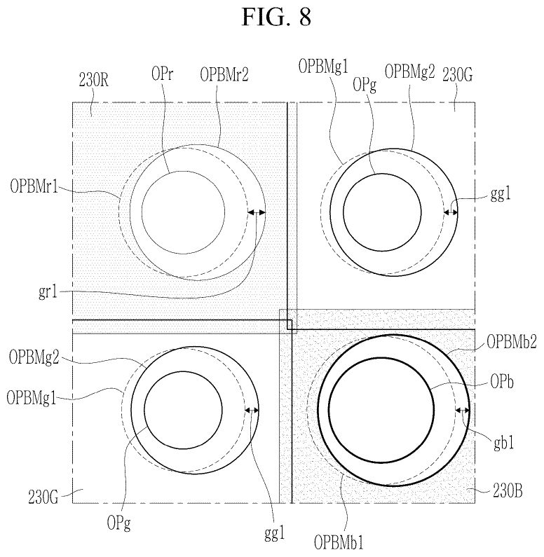

Hereinafter, with reference to FIGS. 8 to 10, the planar structure of each of the 1-1 bending display area DA2-1, the 1-2 bending display area DA2-2, and the 1-3 bending display area DA2-3 will be described in more detail.

FIG. 8 to FIG. 10 are each a plan view showing the positional relationship between openings of each bending display area in a light emitting display device according to one or more embodiments of the present disclosure.

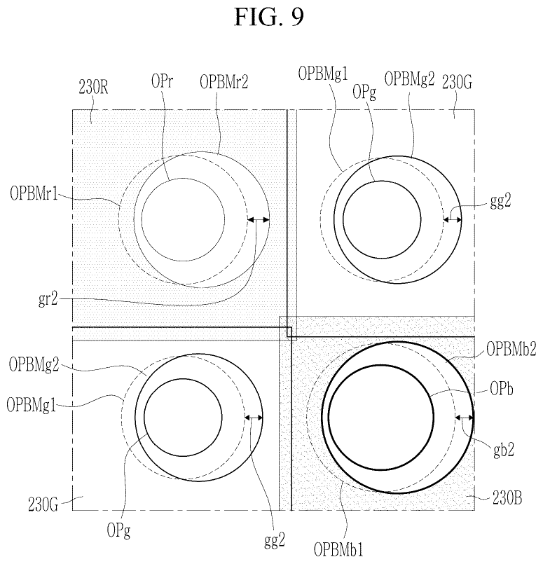

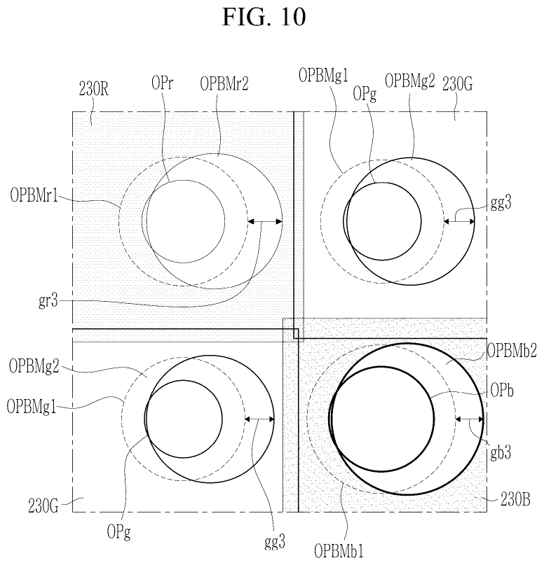

FIG. 8 shows the planar structure of the 1-1 bending display area DA2-1 according to one or more embodiments of the present disclosure, and FIG. 9 shows the planar structure of the 1-2 bending display area DA2-2 according to one or more embodiments of the present disclosure, while FIG. 10 shows the planar structure of the 1-3 bending display area DA2-3 according to one or more embodiments of the present disclosure.

In FIG. 8 to FIG. 10, only four pixels are shown, that is, one red pixel, one blue pixel, and two green pixels. The red pixel is located in the upper left, the blue pixel is located in the lower right, and the green pixels are located in the lower left and upper right.

FIG. 8 to FIG. 10 show the color filters 230R, 230G, and 230B of each pixel and the openings OPr, OPg, and OPb of the pixel defining layer 380 corresponding to the different pixels (the red pixel, green pixel and blue pixel, respectively), and also the openings of each pair of light blocking layers OPBMr1, OPBMg1, OPBMb1, OPBMr2, OPBMg2, OPBMb2 are shown. Here, the openings of the pixel defining layer OPr, OPg, OPb may be located in the lower panel layer, and the openings of the light blocking layer OPBMr2, OPBMg2, OPBMb2 and the color filters 230R, 230G, 230B may be located in the upper panel layer.

The first display openings OPBMr1, OPBMg1, OPBMb1 of the light blocking layer are the openings of the light blocking layer 220 (corresponding to red, green, and blue pixels, respectively), located in the first display area DA1 and are shown as dotted lines for comparison, and the bending openings OPBMr2, OPBMg2, OPBMb2 of the light blocking layer 220 are the openings of the light blocking layer 220 (corresponding to red, green, and blue pixels, respectively) located in the first bending display area DA2.

The bending openings OPBMr2, OPBMg2, OPBMb2 of the light blocking layer 220 have substantially the same size as the first display openings OPBMr1, OPBMg1, OPBMb1 of the light blocking layer 220, and the first display openings OPBMr1, OPBMg1, OPBMb1 of the light blocking layer 220 that are in the first display area DA1 have positional relationships relative to the openings OPr, OPg, OPb of the pixel defining layer 380 located in the first display area DA1, and the bending openings OPBMr2, OPBMg2, OPBMb2 of the light blocking layer 220 in the first bending display area DA2 have positional relationships relative to the second openings OPr, OPg, OPb of the pixel defining layer 380 located in the first bending display area DA2, so that the positional relationships of the first bending display area DA2 are different from the positional relationships of the first display area DA1.

In the first bending display area DA2, the bending openings OPBMr2, OPBMg2, OPBMb2 of the light blocking layer 220 are moved (e.g., positioned farther) in one direction compared to the first display openings OPBMr1, OPBMg1, OPBMb1 of their corresponding light blocking layer 220 in the first display area DA1, where one direction may be in a direction toward the first display area DA1, or it may be in a direction normal (e.g., perpendicular) to a reference axis along which the first bending display area DA2 is bent.

The first display openings OPBMr1, OPBMg1, OPBMb1 of the light blocking layer 220 in the first display area DA1 and the openings OPr, OPg, OPb of the corresponding pixel defining layer 380 have the same center on the plane (e.g., in a plan view), and due to the bending of the light blocking layer 220 in the first bending display area DA2, the bending openings OPBMr2, OPBMg2, OPBMb2 may have a center that is offset from the center of the second openings OPr, OPg, OPb of the corresponding pixel defining layer 380.

In one or more embodiments, the first display openings OPBMr1, OPBMg1, OPBMb1 of the light blocking layer 220 can have the same center as the openings OPr, OPg, OPb of the corresponding pixel defining layer 380, and the radius of the first display openings OPBMr1, OPBMg1, OPBMb1 of the light blocking layer can be larger than the radius of the opening OPr, OPg, OPb of the corresponding pixel defining layer.

In one or more embodiments, the bending openings OPBMr2, OPBMg2, OPBMb2 of the light blocking layer 220 may have the same radius as the first display openings OPBMr1, OPBMg1, OPBMb1 of the light blocking layer 220, but the center can be located at a position offset in one direction from the center of the corresponding pixel defining layer's openings OPr, OPg, OPb.

Here, the one direction may be a direction normal (e.g., perpendicular) to the bending reference axis.

In one or more embodiments, as the bending openings OPBMr2, OPBMg2, OPBMb2 of the light blocking layer 220 changes from the 1-1st bending display area DA2-1 to the 1-3rd bending display area DA2-3, the distance between the centers of the openings OPr, OPg OPb and the centers of the bending openings OPBMr1, OPBMg1, OPBMb1 in the first bending display area DA2 may increase.

For example, in FIG. 8, the maximum gaps between the first display openings OPBMr1, OPBMg1, OPBMb1 of the light blocking layer 220 and the bending openings OPBMr2, OPBMg2, OPBMb2 of the light blocking layer 220 are shown as gr1, gg1, and gb1, respectively, and in FIG. 9, the maximum gaps between the first display openings OPBMr1, OPBMg1, OPBMb1 of the light blocking layer 220 and the bending openings OPBMr2, OPBMg2, OPBMb2 of the light blocking layer 220 are shown as gr2, gg2, and gb2, respectively, while in FIG. 10, the maximum gaps between the first display openings OPBMr1, OPBMg1, OPBMb1 and the bending openings OPBMr2, OPBMg2, OPBMb2 of the light blocking layer 220 are shown as gr3, gg3, and gb3, respectively.

The maximum gaps between the first display openings OPBMr1, OPBMg1, OPBMb1 of the light blocking layer 220 and the bending openings OPBMr2, OPBMg2, OPBMb2 of the corresponding light blocking layers are also called the separation distances.

The separation distances gr1, gg1, gb1 of the bending openings OPBMr2, OPBMg2, OPBMb2 of the light blocking layer 220 of the 1-1 bending display area DA2-1 are the smallest, the separation distances gr2, gg2, gb2 of the bending openings OPBMr2, OPBMg2, OPBMb2 of the light blocking layer 220 of the 1-2 bending display area DA2-2 are the next largest, and the separation distances gr3, gg3, gb3 of the bending openings OPBMr2, OPBMg2, OPBMb2 of the light blocking layer 220 of the 1-3 bending display area DA2-3 are the largest.

The bending openings OPBMr2, OPBMg2, OPBMb2 of the light blocking layer 220 may partially overlap with the openings OPr, OPg, OPb of the pixel defining layer 380 on a plane (e.g., in a plan view) depending on the location.

As described above, as the distance from the first display area DA1 increases, the separation distance between the bending openings OPBMr2, OPBMg2, and OPBMb2 of the light blocking layer 220 increases to form (or provide) the first bending display area DA2 that is angled towards the front, which ensures that the image displayed in the first bending display area DA2 is visible even at a specific angle from the front of the light emitting display device 1000, which has the advantage of increasing the viewing angle.

For example, as shown in the embodiments of FIGS. 8 to 10, the openings OPr, OPg, OPb of the pixel defining layer 380 and the openings OPBMr1, OPBMg1, OPBMb1, OPBMr2, OPBMg2, OPBMb2 of the light blocking layer 220 each have a circular shape, but the present disclosure is not limited to this, and the openings of the pixel defining layer can have an oval shape or one of one or more suitable polygonal shapes, and the corresponding openings of the light blocking layer can have the same or different planar shape.

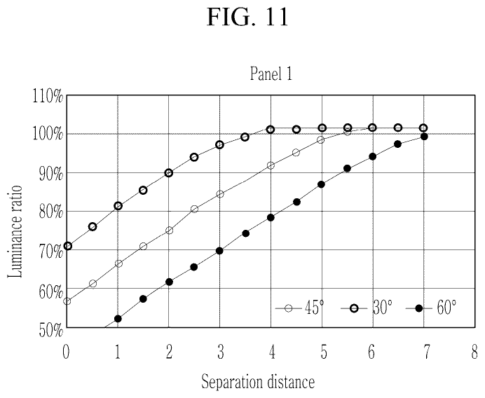

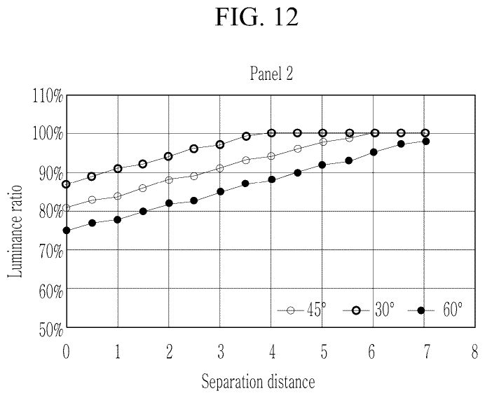

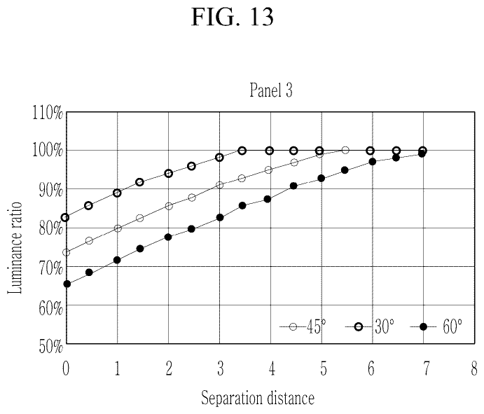

The features of the present disclosure described above will be described in more detail with reference to FIGS. 11 to 13.

FIG. 11 to FIG. 13 are graphs simulating the luminance ratio according to the position of the opening of the bending area. FIG. 11 to FIG. 13 show the results of a simulation based on a green pixel and shows the luminance ratio according to the separation distance at specific viewing angles (30 degrees, 45 degrees, and 60 degrees). Additionally, the graphs in FIGS. 11, 12, and 13 are simulation results for different panels, respectively. Here, the luminance ratio shows the degree to which luminance is reduced at the corresponding angle relative to the front of the panel.

Referring to FIGS. 11 to 13, it can be seen that as the separation distance increases, the luminance ratio at the viewing angle increases and becomes more visible, and if (e.g., when) a certain separation distance is exceeded, the luminance ratio becomes 100% and reaches the maximum value.

At small viewing angles, the luminance ratio can reach 100% at a relatively small separation distance, but at large viewing angles, the luminance ratio can reach 100% at a relatively large separation distance.

The panels utilized in FIGS. 11, 12, and 13 may have different spacing in the third direction DR3 between the pixel defining layer and the light blocking layer, and as the spacing increases, the luminance ratio may be relatively lower at the same viewing angle. Additionally, the panels utilized in FIGS. 11, 12, and 13 may additionally have different anode shapes or sizes.

In FIGS. 11 to 13, the maximum separation distance between the first display openings OPBMr1, OPBMg1, OPBMb1 of the light blocking layer 220 and the bending openings OPBMr2, OPBMg2, OPBMb2 of the corresponding light blocking layer 220 may be up to 6 μm, where the distance may be greater than 0 and less than or equal to 6 μm.

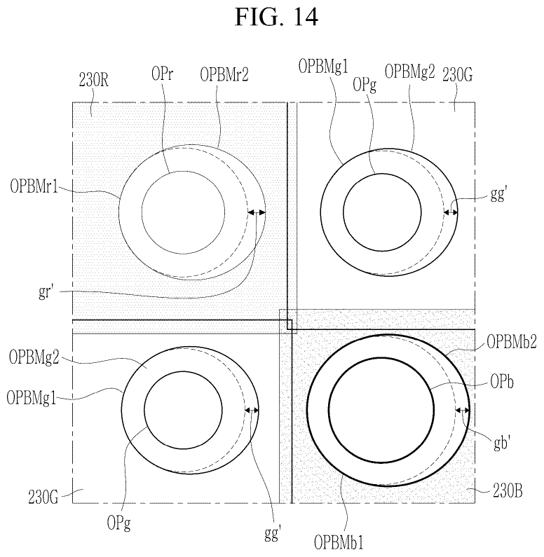

In addition, modified embodiments of the embodiments of FIGS. 8 to 10 will be described with reference to FIGS. 14 to 18.

FIG. 14 to FIG. 18 are each a plan view showing the positional relationship of openings of a bending display area according to one or more embodiments of the present disclosure.

The embodiments of FIGS. 14 to 18 are variations of the one or more embodiments of FIGS. 8 to 10 and may include the following features.

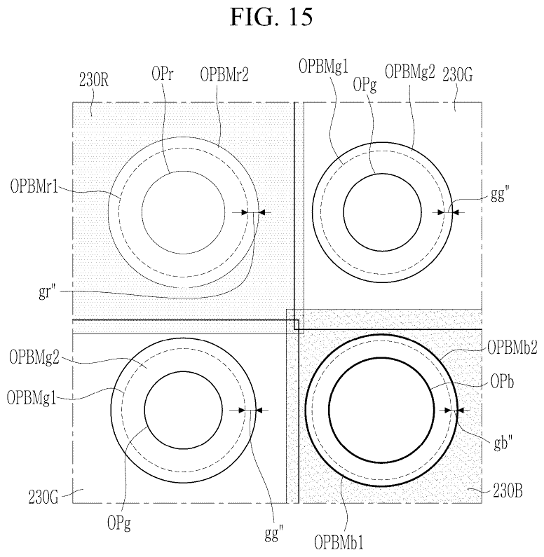

FIG. 14 and FIG. 15 are embodiments in which the bending openings OPBMr2, OPBMg2, OPBMb2 of the light blocking layer 220 are formed in a different shape or size from the first display openings OPBMr1, OPBMg1, OPBMb1 of the light blocking layer 220.

In FIG. 14, the planar shapes of the first display openings OPBMr1, OPBMg1, OPBMb1 of the light blocking layer 220 and the bending openings OPBMr2, OPBMg2, OPBMb2 of the light blocking layer 220 are different from each other.

In the embodiment(s) of FIG. 14, the bending openings OPBMr2, OPBMg2, OPBMb2 of the light blocking layer 220 have a planar shape extending (extending farther) in one direction from the planar shape of the first display openings OPBMr1, OPBMg1, OPBMb1 of the light blocking layer, and the extended distances gr′, gg′, gb′ (hereinafter also referred to as extension distances) may have a value corresponding to the separation distances in FIGS. 11 to 13.

As a result, in the embodiment(s) of FIG. 14, the extended distances gr′, gg′, gb′ may be up to 6 μm, and the extended distances gr′, gg′, gb′ may be greater than 0 and less than or equal to 6 μm.

Here, as shown in FIG. 7, as the distance from the first display area DA1 increases, the extended distances gr′, gg′, gb′ of the bending openings OPBMr2, OPBMg2, OPBMb2 of the light blocking layer 220 may have larger values.

Additionally, the center of the bending opening OPBMr2, OPBMg2, OPBMb2 of the light blocking layer 220 before expansion may coincide with the center of the openings OPr, OPg, OPb of the pixel defining layer 380.

In one or more embodiments, the expansion direction may have two or more directions, and the planar shape of the first display openings OPBMr1, OPBMg1, OPBMb1 of the light blocking layer 220 may have an elliptical or polygonal shape instead of a circular shape, and the light blocking layer 220 may have an elliptical or polygonal shape instead of a circular shape, while the bending openings OPBMr2, OPBMg2, OPBMb2 of the light blocking layer 220 may have a shape extending in at least one direction from the first display openings OPBMr1, OPBMg1, OPBMb1 of the light blocking layer 220.

FIG. 15 shows one or more embodiments in which the first display openings OPBMr1, OPBMg1, OPBMb1 of the light blocking layer 220 and the bending openings OPBMr2, OPBMg2, OPBMb2 of the corresponding light blocking layer 220 have the same planar shape, but are larger in size.

For example, the bending openings OPBMr2, OPBMg2, OPBMb2 of the light blocking layer 220 can have the same center as the openings OPr, OPg, OPb of the pixel defining layer 380, and can have a larger radius than the radius of the first display openings OPBMr1, OPBMg1, OPBMb1 of the light blocking layer 220.

The difference between the radius of the first display openings OPBMr1, OPBMg1, OPBMb1 of the light blocking layer 220 and the radius of the bending openings OPBMr2, OPBMg2, OPBMb2 of the light blocking layer 220 (hereinafter also referred to as the radius difference; gr″, gg″, gb″) can be greater than 0 and less than or equal to 6 μm.

In one or more embodiments, as shown in FIG. 7, the farther away from the first display area DA1, the greater the radius difference gr″, gg″, gb″ of the bending openings OPBMr2, OPBMg2, OPBMb2 of the light blocking layer 220.

In one or more embodiments, the planar shape of the first display openings OPBMr1, OPBMg1, OPBMb1 of the light blocking layer 220 and the bending openings OPBMr2, OPBMg2, OPBMb2 of the light blocking layer 220 may have an elliptical or polygonal shape instead of a circular shape. In embodiments including an elliptical or polygonal shape, the bending openings OPBMr2, OPBMg2, OPBMb2 of the light blocking layer 220 may have larger sides than the first display openings OPBMr1, OPBMg1, OPBMb1 of the corresponding light blocking layer 220. The length difference between one side of the first display openings OPBMr1, OPBMg1, OPBMb1 of the light blocking layer 220 and one side of the bending openings OPBMr2, OPBMg2, OPBMb2 of the light blocking layer 220 may be greater than 0 and less than or equal to 6 μm.

Additionally, as shown in FIG. 7, the length difference between the bending openings OPBMr2, OPBMg2, and OPBMb2 of the light blocking layer 220 may have a larger value as the distance from the first display area DA1 increases.

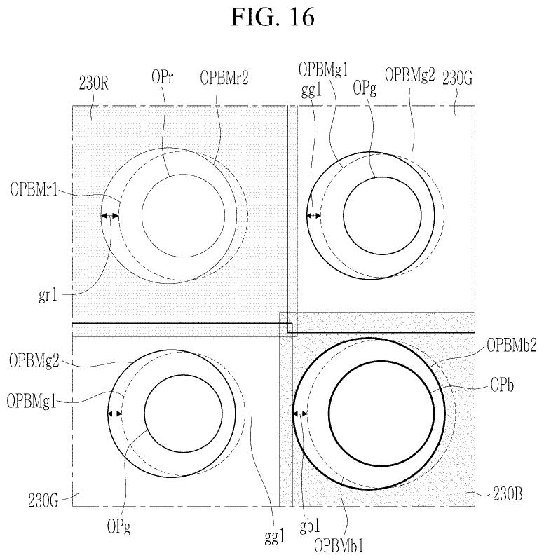

FIG. 16 to FIG. 18 are modified examples of FIG. 8, according to one or more embodiments of the present disclosure. If (e.g., when) there are four bending display areas DA21, DA22, DA23, DA24, as shown in FIG. 4, in the remaining bending display areas DA22, DA23, DA24, the positions (e.g., moving direction) of the bending openings OPBMr2, OPBMg2, OPBMb2 of the light blocking layer 220 relative to the first display openings OPBMr1, OPBMg1, OPBMb1 of the light blocking layer 220 may vary, and positions (e.g., the moving directions) are shown separately in FIGS. 16 to 18.

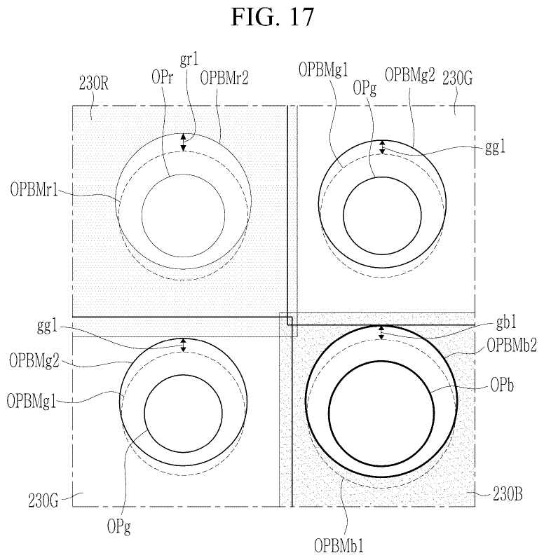

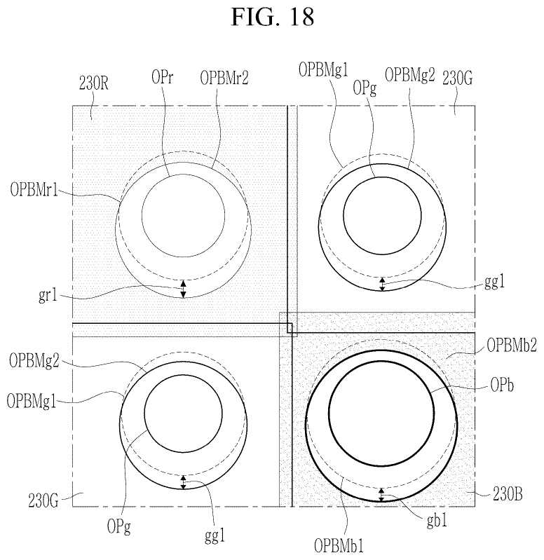

The embodiment of FIG. 8 shows the first side bending display area DA21 among the bending display areas DA21, DA22, DA23, and DA24 in FIG. 4, and the second side bending display area DA22 is shown, for example, in FIG. 16. FIG. 17 shows the third side bending display area DA23, and FIG. 18 shows the fourth side bending display area DA24.

Unlike FIG. 8, in FIG. 16, the direction in which the bending openings OPBMr2, OPBMg2, OPBMb2 of the light blocking layer 220 move (e.g., are positioned) relative to the first display openings OPBMr1, OPBMg1, OPBMb1 of the light blocking layer 220 may be toward the left, and in FIG. 17, the direction in which the bending openings OPBMr2, OPBMg2, OPBMb2 of the light blocking layer 220 move (e.g., are positioned) relative to the first display openings OPBMr1, OPBMg1, OPBMb1 of may be upward, while in FIG. 18, the direction in which the bending openings OPBMr2, OPBMg2, OPBMb2 of the light blocking layer 220 move (e.g., are positioned) relative to the first display openings OPBMr1, OPBMg1, OPBMb1 may be downward.

Here, in the embodiment(s) of FIG. 8, the direction in which the bending openings OPBMr2, OPBMg2, OPBMb2 of the light blocking layer 220 move (e.g., are positioned) relative to the first display openings OPBMr1, OPBMg1, OPBMb1 of the light blocking layer 220 may be to the right.

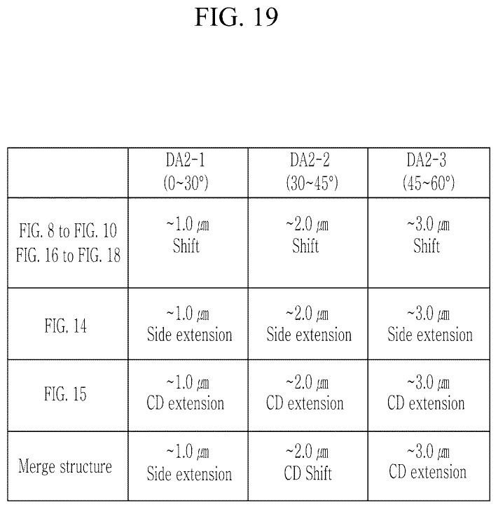

Below, the above embodiments will be described in more detail with reference to FIG. 19, and one or more embodiments in which the numerical range is further limited will also be described in more detail.

FIG. 19 is a table showing the structure of a bending display area according to one or more embodiments of the present disclosure.

As shown in FIG. 7, in embodiments in which the first bending display area DA2 is divided into three areas, the three rows are the 1-1 bending display area DA2-1, the 1-2 bending display area DA2-1, and the 1-3 bending display area DA2-3. In FIG. 19, the range of the bending angle of each area is shown according to one or more embodiments. However, the bending angle of each area may vary depending on the embodiment.

In FIG. 19, each column corresponds to the previously described embodiments as described in the referenced drawing, and the first row shows the separation distance (e.g., maximum gap) of the bending opening of the light blocking layer relative to (e.g., moving in one direction from) the first display opening of the light blocking layer, as shown in FIGS. 8 to 10 and 16 to 18.

The second row is an example in which the bending opening of the light blocking layer is expanded (laterally expanded) in one direction from the planar shape of the first display opening of the light blocking layer, as shown in FIG. 14.

In the third row, the bending opening of the light blocking layer may have a larger radius (CD expansion) than the radius of the first display opening of the light blocking layer, as shown in FIG. 15.

In the fourth row, a merge structure refers to a structure that is a combination of one or more of the embodiments of the first to third rows.

For example, if (e.g., when) the first bending display area DA2 is divided into three areas as shown in FIG. 7, the embodiment(s) of FIG. 14 may be applied to the 1-1 bending display area DA2-1, while one or more embodiments of FIGS. 8 to 10 may be applied to the 1-2 bending display area DA2-2, and one or more embodiments of FIG. 15 may be applied to the 1-3 bending display area DA2-3.

Therefore, in one or more embodiments, the bending openings OPBMr2, OPBMg2, OPBMb2 of the light blocking layer 220 located in the 1-1 bending display area DA2-1 extend in one direction from the planar shape of the first display openings OPBMr1, OPBMg1, OPBMb1 of the light blocking layer 220, and the bending openings OPBMr2, OPBMg2, OPBMb2 may have flat shapes and extended distances gr′, gg′, and gb′, respectively. In addition, the bending openings OPBMr2, OPBMg2, OPBMb2 of the light blocking layer 220 located in the 1-2 bending display area DA2-2, as shown in FIG. 9, may have separation distances (e.g., maximum gaps) gr2, gg2, and gb2, respectively. In addition, the bending openings OPBMr2, OPBMg2, OPBMb2 of the light blocking layer 220 located in the 1-3 bending display area DA2-3 may have a larger radius than the first display openings OPBMr1, OPBMg1, OPBMb1 of the light blocking layer 220. The radius difference values between the radii of the first display openings OPBMr1, OPBMg1, OPBMb1 and the radii of the bending openings OPBMr2, OPBMg2, OPBMb2 of the light blocking layer 220 may be gr “, gg”, and gb “, respectively.

In the merged embodiment described above, the extended distances gr′, gg′, gb′, separation distances gr2, gg2, gb2, and radius differences gr”, gg “, gb” may each be greater than 0 or less than or equal to 6 μm. The further away from the area DA1, the greater the change compared to the first display openings OPBMr1, OPBMg1, OPBMb1, so the extended distances gr′, gg′, gb′ may have the smallest value, and the separation distances (or maximum gaps) gr2, gg2, gb2 may have intermediate value, and the radius differences gr″, gg″, gb″ may have the largest value.

In one or more embodiments, the 1-1 bending display area DA2-1, the 1-2 bending display area DA2-2, and the 1-3 bending display area DA2-3 may be implemented differently. In one or more embodiments, the 1-1 bending display area DA2-1, the 1-2 bending display area DA2-2, and the 1-3 bending display area DA2-3 may be arranged differently from the previously described embodiments.

In FIG. 19, in the 1-1 bending mark area DA2-1, the numerical range of the extended distance (Shift), separation distance (e.g., maximum gap or side extension), and/or radius difference (CD extension) is less than or equal to 1.0 μm. In the 1-2 bending mark area DA2-2, the numerical range of the extended distance (Shift), separation distance (e.g., maximum gap or side extension), and/or radius difference (CD extension) is less than or equal to 2.0 μm. In the 1-3 bending mark area DA2-3, the numerical range of the extended distance (Shift), separation distance (e.g., maximum gap or side extension), and/or radius difference (CD extension) is less than or equal to 3.0 μm.

However, in one or more embodiments, the numerical ranges may be different, and as the distance from the first display area DA1 increases, the numerical ranges of the extended distance (Shift), separation distance (e.g., maximum gap or side extension), and/or radius difference (CD extension) can have gradually larger values in the range, up to 6 μm or less.

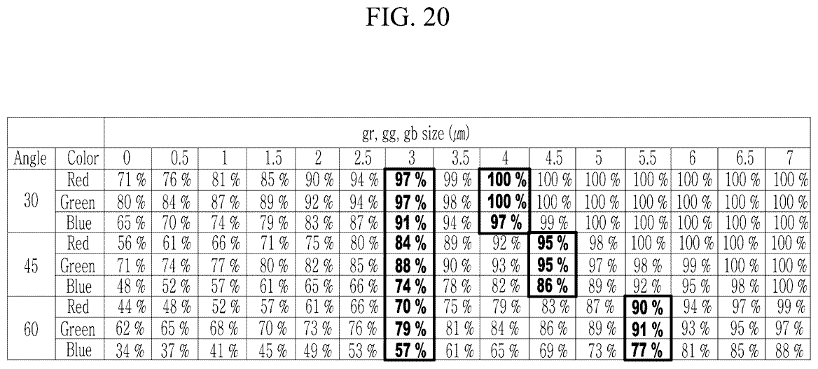

Below, the simulation results of the luminance ratio based on the viewing angle will be described in more detail with reference to FIG. 20. FIG. 20 is a table showing simulated luminance according to the position and viewing angle of the opening.

FIG. 20 shows the luminance ratio for each color (Red, Green, Blue) at a specific viewing angle (30 degrees, 45 degrees, 60 degrees), and the luminance ratio as it varies as a result of the extended distances, separation distances and radius differences (concurrently described as gr, gg, and gb sizes in FIG. 20) by which the bending openings OPBMr2, OPBMg2, OPBMb2 are adjusted.

In FIG. 20, the luminance ratio shows the degree to which luminance is reduced at the corresponding angle relative to the front of the panel.

In the first bending display area DA2, a light blocking layer 220 is located on the light emitting layer EML, and as a result, light is not transmitted at a specific angle, which may reduce the luminance ratio, and the reduced luminance ratio can be seen in FIG. 20 (see, e.g., Angle “0” on FIG. 20).

In FIG. 20, the luminance ratio at each viewing angle when the extended distance, separation distance (e.g., maximum gap), and/or radius difference is 3 μm is shown in bold letters.

When the viewing angle is 30 degrees, it can be seen that the luminance ratio is relatively high, exceeding 90%, and when the viewing angle is 30 degrees, it can be seen that the luminance ratio is equivalent to 100% when the extended distance, separation distance (e.g., maximum gap), and/or radius difference are 4 μm.

In contrast, when the viewing angle is 45 degrees, the extended distance, separation distance (e.g., maximum gap), and/or radius difference must be 4.5 μm to have a luminance ratio equivalent to 95%, and when the viewing angle is 60 degrees, the extended distance, separation distance (e.g., maximum gap), and/or radius difference must be 5.5 μm to have a luminance ratio equivalent to 90%.

Therefore, with reference to FIG. 20, a light emitting display device can be formed by determining the extended distance, separation distance (e.g., maximum gap), and/or radius difference in each embodiment based on the target luminance ratio at a specific viewing angle.

In the above, one or more embodiments in which the first bending display area DA2 is divided into three areas as shown in FIG. 7, and having a certain extended distance, separation distance (e.g., maximum gap), or radius difference is applied to each area was described.

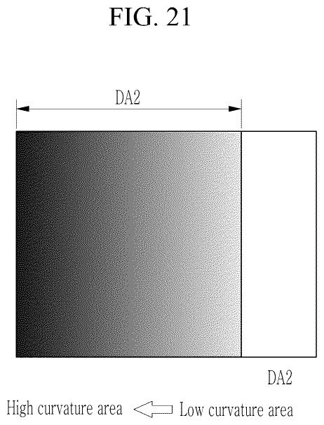

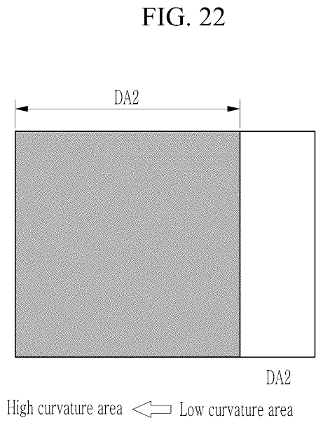

However, in one or more embodiments, the first bending display area DA2 may be divided into a different number of areas, and examples of some of these embodiments will be additionally described with reference to FIGS. 21 and 22.

FIG. 21 and FIG. 22 are plan views schematically dividing a first display area and a bending display area in a light emitting display device according to one or more embodiments of the present disclosure.

In FIG. 21, the first bending display area DA2 is not divided into a separate area (e.g., not divided into three areas as shown, for example, in FIG. 7), but the degree of deformation of the opening of the light blocking layer gradually increases based on the distance from the first display area DA1 increases. This degree of deformation is shown through the deepening of hatching in FIG. 21.

In FIG. 22, the first bending display area DA2 is formed as one area and any one of the embodiments of the present disclosure (e.g., any one of the embodiments shown, for example, in FIG. 8-10 or 14-18) may be applied as a whole. As a result, the extended distance, separation distance, or radius difference of, for example, any one of the previously described embodiments is formed as one and is substantially the same throughout the first bending display area DA2. Although one or more embodiments shown in FIG. 22 may have a lower luminance ratio in certain areas of the first bending display area DA2 relative to one or more embodiments as shown in FIG. 7 or FIG. 21, it can be applied if necessary or desired.

Additionally, in one or more embodiments, the first bending display area DA2 may be divided into two areas or into four or more areas.

According to the aforementioned embodiments, compared to the openings OP of the light blocking layer 220 located in the first display area DA1, the bending openings OPBMr2, OPBMg2, OPBMb2 of the light blocking layer 220 located in the first bending display area DA2 are moved (e.g., positioned), increased in size, or, have a characteristic that is transformed (such as a radius) and differs from a similar characteristic of the openings OP of the light blocking layer 220 located in the first display area DA1.

As a result, the screen displayed on the first bending display area DA2 can be clearly seen above a certain luminance even at a specific viewing angle relative to the front.

Additionally, as the degree of bending in the first bending display area DA2 increases, the degree to which the bending opening of the light blocking layer is moved (positioned), enlarged, or transformed may also increase.

In one or more embodiments, if (e.g., when) the colors of light to be emitted pixels are different, even if the pixels are located at the same distance from the first display area DA1, the bending opening of the light blocking layer may be moved (positioned), enlarged, or transformed to a different extent.

Hereinafter, the entire cross-sectional structure of the light emitting display device will be described in more detail, focusing on the first display area DA1 of the light emitting display device.

FIG. 23 is a cross-sectional view of a light emitting display device according to one or more embodiments of the present disclosure.

In FIG. 23, the display area DA may be the first display area DA1, and the optical sensor area OPS may be an area located in a portion of the first display area DA1 and may be an area where an optical sensor is located on the back.

Referring to FIG. 23, a metal layer BML is located on the substrate 110. The substrate 110 may include a material that has rigid properties and does not bend, such as glass, or may include a flexible material that can bend, such as plastic or polyimide. In the case of a flexible substrate, as shown in FIG. 23, it may have a double-layer structure of polyimide and a barrier layer formed of an inorganic insulating material thereon.

The metal layer BML may be formed at a position that overlaps the channel of the subsequent first semiconductor layer ACT (P—Si) on a plane (e.g., in a plan view). The metal layer BML is also called the lower shielding layer and may include a metal or a metal alloy such as copper (Cu), molybdenum (Mo), aluminum (AI), and/or titanium (Ti), and may additionally include amorphous silicon, and may be composed of a single layer or multiple layers.

A buffer layer 111 covering the substrate 110 and the metal layer BML may be located on the substrate 110. The buffer layer 111 serves to block or reduce the penetration of impurities into the first semiconductor layer ACT (P—Si) and is an inorganic insulating layer containing a silicon oxide (SiOₓ), a silicon nitride (SiNₓ), a silicon oxynitride (SiOₓN_{y}), and/or the like.

A first semiconductor layer ACT (P—Si) is located on the buffer layer 111. The first semiconductor layer ACT (P—Si) may be included in a driving transistor included in the pixel and may be a transistor containing a polycrystalline semiconductor. The first semiconductor layer ACT (P—Si) has a region on both sides (e.g., opposite sides) of the channel that have conductive layer characteristics through plasma treatment or doping, and serve as a first electrode and a second electrode.

A first gate insulating layer 141 may be located on the first semiconductor layer ACT (P—Si). The first gate insulating layer 141 may be an inorganic insulating layer containing a silicon oxide (SiOₓ), a silicon nitride (SiNₓ), and/or a silicon oxynitride (SiOₓN_{y}).

A first gate conductive layer including the gate electrode GAT1 of the driving transistor may be positioned on the first gate insulating layer 141. The first gate conductive layer includes gate electrodes of each polycrystalline transistor including a polycrystalline semiconductor (such as, for example, the low-temperature polycrystalline silicon thin film transistor (LTPS TFT) of FIG. 23) as well as the driving transistor. The first gate conductive layer may include a metal or metal alloy such as copper (Cu), molybdenum (Mo), aluminum (AI), and/or titanium (Ti), and may be composed of a single layer or multiple layers.

After forming (or providing) the first gate conductive layer, plasma treatment or a doping process may be performed to make the exposed area of the first semiconductor layer ACT (P—Si) conductive. For example, the first semiconductor layer ACT (P—Si) covered by the first gate conductive layer is not conductive, and the portion of the first semiconductor layer ACT (P—Si) that is not covered by the first gate conductive layer may have the same characteristics as the conductive layer after a plasma treatment or doping process, for example.

A second gate insulating layer 142 may be positioned on the first gate conductive layer and the first gate insulating layer 141. The second gate insulating layer 142 may be an inorganic insulating layer containing a silicon oxide (SiOₓ), a silicon nitride (SiNₓ), and/or a silicon oxynitride (SiOₓN_{y}).

A second gate conductive layer including the first storage electrode GAT2 (Cst) of the storage capacitor Cst may be positioned on the second gate insulating layer 142. The first storage electrode GAT2 (Cst) overlaps the gate electrode GAT1 of the driving transistor to form (or provide) a storage capacitor Cst.

In one or more embodiments, the second gate conductive layer may further include a lower shielding layer GAT2 (BML) located below the transistor including an oxide semiconductor. The lower shielding layer GAT2 (BML) may overlap the subsequently formed oxide semiconductor layer ACT2 (IGZO). The second gate conductive layer may include a metal or metal alloy such as copper (Cu), molybdenum (Mo), aluminum (AI), and/or titanium (Ti), and may be composed of a single layer or multiple layers.

A first interlayer insulating layer 161 may be positioned on the second gate conductive layer. The first interlayer insulating layer 161 may include an inorganic insulating layer containing a silicon oxide (SiOₓ), a silicon nitride (SiNₓ), and/or a silicon oxynitride (SiOₓN_{y}). In one or more embodiments, the inorganic insulating material may be formed thickly.

The oxide semiconductor layer ACT2 (IGZO) may be located on the first interlayer insulating layer 161. Additionally, the oxide semiconductor layer ACT2 (IGZO) may be included in an oxide transistor including an oxide semiconductor (e.g., an oxide thin film transistor (Oxide TFT in FIG. 23)).

A third gate insulating layer 143 may be located on the oxide semiconductor layer ACT2 (IGZO). The third gate insulating layer 143 may be located on the entire surface of the oxide semiconductor layer and the first interlayer insulating layer 161. The third gate insulating layer 143 may include an inorganic insulating layer containing a silicon oxide (SiOₓ), a silicon nitride (SiNₓ), and/or a silicon oxynitride (SiOₓN_{y}).

A third gate conductive layer GAT3 may be located on the third gate insulating layer 143. The third gate conductive layer GAT3 may include a connection electrode connected to the gate electrode of the oxide transistor and the lower shielding layer GAT2 (BML). The third gate conductive layer GAT3 may contain a metal or metal alloy such as copper (Cu), molybdenum (Mo), aluminum (AI), and/or titanium (Ti), and may be composed of a single layer or multiple layers.

A second interlayer insulating layer 162 may be positioned on the third gate conductive layer GAT3. The second interlayer insulating layer 162 may have a single-layer or multi-layer structure. The second interlayer insulating layer 162 may include an inorganic insulating material such as a silicon nitride (SiNₓ), a silicon oxide (SiOₓ), and/or a silicon oxynitride (SiOₓN_{y}), and, in one or more embodiments, may include an organic material.

A first data conductive layer SD1 including a connection electrode connected to one electrode of a polycrystalline transistor (e.g., the LTPS TFT of FIG. 23) and/or an oxide transistor (e.g., the Oxide TFT of FIG. 23) may be positioned on the second interlayer insulating layer 162. The first data conductive layer SD1 may include a metal or metal alloy such as aluminum (AI), copper (Cu), molybdenum (Mo), and/or titanium (Ti), and may be composed of a single layer or multiple layers.

A first organic layer 181 may be positioned on the first data conductive layer. The first organic layer 181 may be an organic insulating layer containing an organic material, and the organic material may include one or more materials of (e.g., selected from among) the group including (e.g., consisting of) polyimide, polyamide, acrylic resin, benzocyclobutene, and/or phenol resin.

A second data conductive layer including an anode connection electrode ACM2 that transfers the output current of the driving transistor to the anode may be positioned on the first organic layer 181. The anode connection electrode ACM2 is connected to the connection electrode of the first data conductive layer through the lower organic layer opening OP3 located in the first organic layer 181. The second data conductive layer may include a metal or metal alloy such as aluminum (Al), copper (Cu), molybdenum (Mo), and/or titanium (Ti), and may be composed of a single layer or multiple layers.

The second organic layer 182 and the third organic layer 183 are located on the second data conductive layer. The second organic layer 182 and the third organic layer 183 may be organic insulating layers and may include one or more materials of (e.g., selected from among) the group including (e.g., consisting of) polyimide, polyamide, acrylic resin, benzocyclobutene, and/or phenol resin. In one or more embodiments, the third organic layer 183 may not be provided.

An anode connection opening OP4 is formed (provided) in the second organic layer 182 and the third organic layer 183, through which the anode and the anode connection electrode ACM2 are electrically connected.

The anode (see, e.g., “Anode” in FIG. 23) is formed (provided) on the third organic layer 183. The anode receives current from the pixel circuit through the anode connection opening OP4. The anode may be composed of a single layer containing a transparent conductive oxide film and a metal material, or multiple layers containing these. The transparent conductive oxide film can include ITO (Indium Tin Oxide), poly-ITO, IZO (Indium Zinc Oxide), IGZO (Indium Gallium Zinc Oxide), and/or ITZO (Indium Tin Zinc Oxide), and the metal material can include silver (Ag), molybdenum (Mo), copper (Cu), gold (Au), and/or aluminum (Al).

The pixel defining layer 380 is located on the anode, and the opening OP of the pixel defining layer 380 is formed to overlap the anode. The pixel defining layer 380 may be formed of a negative type or kind of black organic material. The black organic material may include a light blocking material, and the light blocking material may include carbon black, carbon nanotubes, a resin or paste containing a black dye, metal particles such as nickel, aluminum, molybdenum, and/or an alloy thereof, metal oxide particles, chromium nitride, and/or the like.

The pixel defining layer 380 contains a light blocking material and is black in color, and may have characteristics of absorbing/blocking light rather than reflecting it.

Because the negative type or kind uses organic materials, it can have the property of removing the part covered by the mask.

The anode connection opening OP4 is not exposed by the opening OP of the pixel defining layer 380 and has a structure that overlaps the pixel defining layer 380 on a plane (e.g., in a plan view).

Because the anode connection opening OP4 does not overlap the opening OP of the pixel defining layer 380 on a plane, it has a structure that overlaps the pixel defining layer 380 on a plane (e.g., in a plan view).

FIG. 23 does not include the light blocking layer 220, but instead includes a structure that blocks light by overlapped color filters 230R and 230B.

Therefore, the overlapped color filters 230R and 230B and the anode connection opening OP4 may overlapping these color filters 230R and 230B in a plan view.

A green color filter 230G of a different color may be located in the opening OPCF of the overlapped color filters 230R and 230B.

In one or more embodiments, some of the lower organic layer openings OP3 (first lower organic layer openings) overlap at least a portion of the openings OPCF of the overlapped color filters 230R and 230B on a plane (e.g., in a plan view), and the remaining lower organic layer openings OP3, that is, the second lower organic layer opening, overlaps the overlapped color filters 230R and 230B on a plane (e.g., in a plan view).

In one or more embodiments, all lower organic layer openings OP3 overlap with the pixel defining layer 380 on a plane (e.g., in a plan view).

Due to the positional relationship between the anode and the anode connection opening OP4 below it, external light may not be reflected asymmetrically and color spreading (color separation) may not occur.

A spacer 385 having a stepped structure is formed on the pixel defining layer 380. The spacer 385 has a relatively high first part 385-1 and a second part 385-2 that is lower in height than the first part 385-1, and is located around the first part 385-1.

The spacer 385 can reduce the incidence of defects due to pressing pressure and may increase the scratch strength on the display panel DP, and also may increase the adhesion with the functional layer FL located on the top of the spacer 385 to prevent or reduce moisture from the outside and/or air from infiltrating.

In addition, high adhesive strength has the advantage of eliminating the problem of poor adhesion between layers if (e.g., when) the display panel DP has flexible characteristics and is folded and unfolded.

In one or more embodiments, the pixel defining layer 380 may be formed as a negative type or kind, and the spacer 385 may be formed as a positive type or kind, and may include the same materials.

The light emitting layer EML is formed (provided) within the opening OP of the pixel defining layer 380, and may be located on the anode.

The light emitting layer EML may be formed of an organic light emitting material, and adjacent light emitting layers EML in the display area DA may display different colors.

In one or more embodiments, each light emitting layer EML may display light of the same color due to the color filters 230R, 230G, and 230B located at the top.

The functional layer FL is located on the emitting layer EML, the spacer 385, and the exposed pixel defining layer 380, and the functional layer FL may be formed (provided) on the front surface of the display panel DP.

The functional layer FL may include an electron injection layer, an electron transport layer, a hole transport layer, and/or a hole injection layer, and the functional layer FL may be located above and/or below the light emitting layer EML.

For example, the hole injection layer, hole transport layer, light emitting layer EML, electron transport layer, electron injection layer, and cathode (Cathode) are sequentially located on the anode (Anode), and among the functional layers FL, the hole injection layer and hole transport layer can be located under the light emitting layer EML, and the electron transport layer and electron injection layer can be located above the light emitting layer EML.

The cathode may be formed as a light-transmitting electrode or a reflective electrode.

In one or more embodiments, the cathode may be a transparent or translucent electrode, and may be lithium (Li), calcium (Ca), lithium/calcium fluoride (LiF/Ca), lithium/aluminum fluoride (LiF/AI), aluminum (AI), silver (Ag), and/or magnesium (Mg), and their compounds can be formed as a metal thin film with a small work function.

Additionally, a transparent conductive oxide (TCO) film, such as indium tin oxide (ITO), indium zinc oxide (IZO), zinc oxide (ZnO), and/or indium oxide (In₂O₃) may be further arranged on the metal thin film.

The cathode may be formed integrally (or provided) over the entire surface of the display panel DP.

An encapsulation layer 400 is located on the cathode. The encapsulation layer 400 includes at least one inorganic layer and at least one organic layer, and as shown, for example, in FIG. 5, the encapsulation layer 400 may include a first inorganic encapsulation layer 401, an organic encapsulation layer 402, and a second inorganic encapsulation layer 403, which is the triple layer structure. The encapsulation layer 400 may be utilized to protect the light emitting layer EML made of an organic material from moisture or oxygen that may enter from the outside.

In one or more embodiments, the encapsulation layer 400 may include a structure in which an inorganic layer and an organic layer are further sequentially stacked.

Sensing insulating layers 501, 510, and 511 and a plurality of sensing electrodes 540 and 541 are positioned on the encapsulation layer 400 for touch detection.

In one or more embodiments, as shown, for example in FIG. 23, touch is detected in a capacitive type or kind utilizing two sensing electrodes 540 and 541, but in one or more embodiments, touch can also be detected in a self-capacitive type or kind utilizing only one sensing electrode.

The plurality of sensing electrodes 540 and 541 may be insulated with the sensing insulating layers 501, 510, and 511 interposed therebetween, and some may be electrically connected through openings located in the sensing insulating layers 501, 510, and 511. Here, the sensing electrodes 540 and 541 can include metals or metal alloys such as aluminum (AI), copper (Cu), silver (Ag), gold (Au), molybdenum (Mo), titanium (Ti), and/or tantalum (Ta), and can be composed of a single layer or multiple layers.

In one or more embodiments, a lower sensing insulating layer 501 is located below the lower sensing electrode 541, and an intermediate sensing insulating layer 510 is located between the lower sensing electrode 541 and the upper sensing electrode 540. The upper sensing insulating layer 511 is located between the upper sensing electrode 540 and the color filters 230R, 230B, and 230G.

The upper sensing insulating layer 511 may be located below the color filters 230R, 230G, and 230B.

At least a portion of the sensing electrodes 540 and 541 may have a structure that overlaps the anode connection opening OP4 on a plane (e.g., in a plan view).

Color filters 230R, 230G, and 230B are located on the upper sensing electrode 540.

In one or more embodiments, as shown, for example, in FIG. 23, there is no inclusion of a light blocking layer, and the role of the light blocking layer is performed by the overlapped color filters 230R and 230B, where the overlapped color filters 230R and 230B can be positioned to overlap with the sensing electrodes 540 and 541 on a plane (e.g., in a plan view).

The overlapped color filters 230R and 230B have an opening OPCF, and the opening OPCF of the overlapped color filters 230R and 230B overlaps the opening OP of the pixel defining layer 380 on a plane (e.g., in a plan view).

Additionally, the opening OPCF of the overlapped color filters 230R and 230B may be wider than the opening OP of the pixel defining layer 380.

As a result, because the anode that overlaps the opening OP of the pixel defining layer 380 (i.e., is exposed by the opening OP of the pixel defining layer 380) also overlaps the color filters 230R and 230B, it is possible to have a structure that is not obscured in a plan view.

This is to ensure that the anode and the light emitting layer EML capable of displaying an image are not obscured by the overlapped color filters 230R and 230B and the sensing electrodes 540 and 541.

In one or more embodiments, the overlapped color filters 230R, 230B have a structure that overlaps the anode connection opening OP4 and the second lower organic layer opening (see the second lower organic layer opening OP3C of FIG. 5) on a plane (e.g., in a plan view), but does not overlap the first lower organic layer opening (see the first lower organic layer opening OP3U in FIG. 5) on a plane (e.g., in a plan view).

A green color filter 230G of a different color may be located within the opening OPCF of the overlapped color filters 230R and 230B.

In one or more embodiments, the color filters 230R, 230G, and 230B may be replaced with a color conversion layer or may further include a color conversion layer. The color conversion layer may include quantum dots.

A planarization layer 550 covering the color filters 230R, 230G, and 230B is positioned on the color filters 230R, 230G, and 230B. The planarization layer 550 is utilized to planarize the upper surface of the light emitting display device, and may be a transparent organic insulating layer containing one or more materials of (e.g., selected from among) the group including (e.g., consisting of) polyimide, polyamide, acrylic resin, benzocyclobutene, and/or phenol resin.

In one or more embodiments, a relatively low refractive layer (e.g., a refractive layer with a relatively low refractive index) and an additional planarization layer may be further positioned on the planarization layer 550 to improve front visibility and light output efficiency of the display device.

Light can be refracted and emitted toward the front by an additional flattening layer with a relatively low refractive characteristic and a relatively high refractive characteristic.

In one or more embodiments, the planarization layer 550 may not be provided and a relatively low refractive layer and an additional planarization layer may be located directly on the color filter 230.

In one or more embodiments, a polarizing plate is not included on top of the planarization layer 550.

A polarizer can play a role in preventing or substantially preventing display quality from deteriorating if (e.g., when) external light is incident and reflected by an anode, and/or the like, and is visible to the user.

However, in the embodiment of FIG. 23, the side of the anode is covered with the pixel defining layer 380 to reduce the degree of reflection from the anode, and overlapped color filters 230R and 230B are also formed to reduce the degree of incident light. Therefore, the light emitting display device of FIG. 23 already includes a structure that prevents or reduces deterioration of display quality due to reflection.

Therefore, in one or more embodiments, it may not be desired or necessary separately form (or provide) the polarizer on the front of the display panel DP.

Also, in the embodiment of FIG. 23, the anode, which is exposed through the opening OP of the pixel defining layer 380, which is a part where external light can be reflected, is formed flatly so that light is not reflected asymmetrically from the anode.

In one or more embodiments, the anode connection opening OP4, which is the most uneven portion of the anode, is covered by the pixel defining layer 380 and the overlapped color filters 230R and 230B to prevent or reduce the likelihood of light from being reflected asymmetrically.

In one or more embodiments, FIG. 23 shows, in addition to the stacked structure of the display area DA, a stacked structure of the optical sensor area OPS that is formed to allow light to transmit through a portion of the display area DA.

The optical sensor area OPS includes (e.g., consists of) only transparent layers so that light can pass through, and there is no conductive layer or semiconductor layer. The optical sensor area OPS includes an opening (hereinafter referred to as an additional opening) at a position corresponding to the pixel defining layer 380, the light blocking layer, and the color filter 230, so that it can have a structure that does not block or reduce light.

In one or more embodiments, the buffer layer 111, which is an inorganic insulating film, is positioned on the substrate 110, and the first gate insulating layer 141 and the second gate insulating layer 142, which are inorganic insulating films, are sequentially positioned thereon.

Additionally, in one or more embodiments, the first interlayer insulating layer 161, the third gate insulating layer 143, and the second interlayer insulating layer 162, which are inorganic insulating films, are sequentially stacked on the second gate insulating layer 142. On the second interlayer insulating layer 162, the first organic layer 181, the second organic layer 182, and the third organic layer 183, which are organic insulating layers, are sequentially stacked. The functional layer FL may be located on the third organic layer 183, and a cathode may be located on the third organic layer 183.

The encapsulation layer 400 may be positioned on the cathode, and sensing insulating layers 501, 510, and 511 may be sequentially positioned on top of the cathode. The encapsulation layer 400 may have a triple-layer structure including a first inorganic encapsulation layer 401, an organic encapsulation layer 402, and a second inorganic encapsulation layer 403, as shown in FIG. 5.

Additionally, the sensing insulating layers 501, 510, and 511 may all be inorganic insulating layers.

In one or more embodiments, referring to FIG. 23, additional openings located on the color filter 230 are each positioned above the encapsulation layer 400 and the sensing insulation layers 501, 510, and 511 so that light is not blocked by the color filter 230 in the optical sensor area OPS.

The planarization layer 550 may be positioned on the sensing insulating layers 501, 510, and 511.

The optical sensor area OPS as described above does not include a metal layer, a first semiconductor layer, a first gate conductive layer, a second gate conductive layer, an oxide semiconductor layer, a third gate conductive layer, a first data conductive layer, a second data conductive layer, or the anode.

Additionally, the light emitting layer EML and the sensing electrodes 540 and 541 are not formed in the optical sensor area OPS.

Additionally, an additional opening is formed in the pixel defining layer 380, the light blocking layer, and the color filter 230 in the optical sensor area (OPS), so that the pixel defining layer 380, the light blocking layer, and the color filter 230 are not formed in the optical sensor area OPS.

In the above, one or more embodiments in which a total of three organic layers are formed, and an anode connection opening is formed in the second organic layer and the third organic layer were described. However, in one or more embodiments, at least two organic layers may be formed, and the anode connection opening may be located in the upper organic layer located away from the substrate, and the lower organic layer opening may be located in the lower organic layer.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

### REFERENCE NUMERALS

1000: light emitting display device
DA: display area
DA1: first display area
DA2, DA-S, DA2-1, DA2-2, DA2-3: bending display area
DP: display panel
220: light blocking layer
230, 230R, 230G, 230B: color filter
380: pixel defining layer
OPBM: opening of a light blocking layer
OPCF: opening of color filter
OPBMr1, OPBMg1, OPBMb1: first display opening
OPBMr2, OPBMg2, OPBMb2: bending opening
OP, OPr, OPg, OPb: opening of the pixel defining layer
385: spacer
400: encapsulation layer
501, 510, 511: sensing insulation layer
540, 541: sensing electrode
550: planarization layer
ACM2: anode connection electrode
ACT (P—Si): first semiconductor layer
ACT2 (IGZO): oxide semiconductor layer
Anode: anode
BML: metal layer
Cathode: cathode
EML: light emitting layer
FL: functional layer
BRL: border
50, 51: driving part
PA1, PA2: peripheral area
TA1, TA2, TA-S: transmitting portions
WU: cover window
HM: housing
OPS: optical sensor area

What is claimed is:

1. A light emitting display device, comprising:
a substrate comprising a first display area and a bending display area;
an anode on the substrate;
a pixel defining layer having an opening exposing at least a portion of the anode;
a light emitting layer within the opening of the pixel defining layer;
a cathode covering the pixel defining layer and the light emitting layer;
an encapsulation layer covering the cathode; and
a light blocking layer on the encapsulation layer and having an opening corresponding to the opening of the pixel defining layer,
wherein,
the opening of the pixel defining layer comprises a first opening in the first display area and a second opening in the bending display area,
the opening of the light blocking layer comprises a first display opening in the first display area and overlapping the first opening in a plan view of the first display area, and a bending opening in the bending display area and overlapping the second opening in a plan view of the bending display area,
the bending opening of the light blocking layer has the same size as the first display opening of the light blocking layer, and
a positional relationship between the first display opening of the light blocking layer in the first display area and the first opening of the pixel defining layer is different from a positional relationship between the bending opening of the light blocking layer in the bending display area and the second opening of the pixel defining layer.

2. The light emitting display device of claim 1, wherein a position of the bending opening relative to the second opening is farther in one direction compared to a position of the first display opening relative to the first opening.

3. The light emitting display device of claim 2, wherein the one direction is toward the first display area.

4. The light emitting display device of claim 3, wherein the one direction is perpendicular to a reference axis to which the light emitting display device is bent.

5. The light emitting display device of claim 3, wherein in the first display area, the first display opening of the light blocking layer and the first opening of the pixel defining layer have the same center in the plan view of the first display area.

6. The light emitting display device of claim 5, wherein a center of the bending opening of the light blocking layer in the bending display area is offset from a center of the second opening of the pixel defining layer.

7. The light emitting display device of claim 3, wherein the first display area has a flat display surface, and the bending display area is outside the first display area and is bent from the flat display surface.

8. The light emitting display device of claim 3, wherein
the substrate comprises a plurality of bending display areas comprising the bending display area, each of the bending display areas comprising a bending opening and a second opening, each of the bending openings overlapping a corresponding one of the second openings in a plan view of a respective one of the bending display areas,
a separation distance is a maximum gap between the first display opening of the light blocking layer and a respective bending opening of the bending openings of the light blocking layer when the first display opening and the respective bending opening are positionally compared relative to the first opening and a corresponding one of the second openings, and
the separation distance increases as a distance from the first display area increases.

9. The light emitting display device of claim 8, wherein the separation distance is greater than 0 and less than or equal to 6 μm.

10. The light emitting display device of claim 3, wherein
the substrate comprises a plurality of bending display areas comprising the bending display area, each of the bending display areas comprising a bending opening and a second opening, each of the bending openings overlapping a corresponding one of the second openings in a plan view of a respective one of the bending display areas,
a separation distance is a maximum gap between the first display opening of the light blocking layer and a respective bending opening of the bending openings of the light blocking layer when the first display opening and the respective bending opening are positionally compared relative to the first opening and a corresponding one of the second openings, and
the separation distance of a bending opening of the bending openings located farther from the first display area is greater than the separation distance of a bending opening of the bending openings located closer to the first display area.

11. The light emitting display device of claim 10, wherein
the plurality of bending display areas comprise a 1-1 bending display area, a 1-2 bending display area, and a 1-3 bending display area,
the 1-1 bending display area is located closest to the first display area, the 1-2 bending display area is between the 1-1 bending display area and the 1-3 bending display area, and the 1-3 bending display area is located farthest from the first display area, and
the separation distance of the light blocking layer in the 1-1 bending display area is the smallest, the separation distance of the light blocking layer in the 1-3 bending display areas is the largest, and the separation distance of the light blocking layer in the 1-2 bending display areas is the second largest.

12. The light emitting display device of claim 11, wherein
the separation distances of the plurality of bending display areas are each greater than 0 and less than or equal to 6 μm.

13. A light emitting display device, comprising:
a substrate comprising a first display area and a bending display area;
an anode on the substrate;
a pixel defining layer having an opening exposing at least a portion of the anode;
a light emitting layer within the opening of the pixel defining layer;
a cathode covering the pixel defining layer and the light emitting layer;
an encapsulation layer covering the cathode; and
a light blocking layer on the encapsulation layer and having an opening corresponding to the opening of the pixel defining layer,
wherein the opening of the pixel defining layer comprises a first opening in the first display area and a second opening in the bending display area,
the opening of the light blocking layer comprises a first display opening in the first display area and overlapping the first opening in a plan view of the first display area, and a bending opening in the bending display area and overlapping the second opening in a plan view of the bending display area, and
the bending opening of the light blocking layer has a different shape or size from the first display opening of the light blocking layer.

14. The light emitting display device of claim 13, wherein
a planar shape of the bending opening relative to the second opening extends farther in one direction compared to a planar shape of the first display opening relative to the first opening.

15. The light emitting display device of claim 14, wherein
an extension distance is a distance between the planar shape of the bending opening and the planar shape of the first display opening when the bending opening and the first display opening are positionally compared relative to the second opening and the first opening, respectively, and
the extension distance is greater than 0 and less than or equal to 6 μm.

16. The light emitting display device of claim 15, wherein the substrate comprises a plurality of bending display areas comprising the bending display area, each of the bending display areas comprising a bending opening, and
the extension distance increases as a distance from the first display area increases.

17. The light emitting display device of claim 13, wherein
the bending opening has the same center as the second opening and has a radius or one side larger than the first display opening of the light blocking layer.

18. The light emitting display device of claim 17, wherein a difference between a radius or one side of the first display opening and a radius or one side of the bending opening is greater than 0 and less than or equal to 6 μm.

19. The light emitting display device of claim 18, wherein
the substrate a plurality of bending display areas comprising the bending display areas, each of the bending display areas comprising a bending opening, and the bending openings increase in size as a distance from the first display area increases.

20. The light emitting display device of claim 13, wherein
the bending display area is divided into a 1-1 bending display area, a 1-2 bending display area, and a 1-3 bending display area, the 1-1 bending display area is closest to the first display area, the 1-2 bending display area is between the 1-1 bending display area and the 1-3 bending display area, and the 1-3 bending display area is farthest from the first display area,
each of the 1-1 bending display area, the 1-2 bending display area, and the 1-3 bending display area comprise a bending opening and a second opening, each of the bending openings overlapping a corresponding second opening of the second openings in a plan view of a corresponding one of the 1-1, 1-2, and 1-3 bending display areas,
in one selected from among the 1-1 bending display area, the 1-2 bending display area, and the 1-3 bending display area, a planar shape of the bending opening relative to the corresponding second opening extends farther in one direction compared to a planar shape of the first display opening relative to the first opening,
in another one selected from among the 1-1 bending display area, the 1-2 bending display area, and the 1-3 bending display area, the bending opening has the same center as the corresponding second opening and has a larger radius or one side than the first display opening of the light blocking layer,
in the remaining one selected from among the 1-1 bending display area, the 1-2 bending display area, and the 1-3 bending display area, the bending opening has the same size as the first display opening of the light blocking layer, and a position of the bending opening relative to the corresponding second opening is farther in one direction compared to a position of the first display opening relative to the first opening.
